(19) United States
(12) Patent Application Publication
(10) Pub. No.: US 2021/0391258 A1
(43) Pub. Date: Dec. 16, 2021

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Jae Taek KIM, Icheon-si Gyeonggi-do (KR); Hye Yeong JUNG, Icheon-si Gyeonggi-do (KR)

(73) Assignee: SK hynix Inc., Icheon-si Gyeonggi-do (KR)

(21) Appl. No.: 17/095,169

(22) Filed: Nov. 11, 2020

(30) Foreign Application Priority Data
Jun. 15, 2020 (KR) 10-2020-0072564

(51) Int. Cl. H01L 23/528; H01L 21/768

(52) U.S. Cl. CPC H01L 23/5283; H01L 23/5226; H01L 21/76816; H01L 21/76892

(57) ABSTRACT

A semiconductor device includes: a first stack structure with first insulating patterns and first conductive patterns, alternately stacked, the first stack structure with a first stepped structure that is defined by the first insulating patterns and the first conductive patterns; a second stack structure with second insulating patterns and second conductive patterns, alternately stacked on the first stack structure; and a first protrusion stack structure protruding laterally toward the first stepped structure from the second stack structure, the first protrusion stack structure with first protrusion insulating patterns and first protrusion conductive patterns, alternately stacked on the first stack structure. A sidewall of the first protrusion stack structure includes side surfaces of the first protrusion insulating patterns and side surfaces of the first protrusion conductive patterns, which form a common surface.

### CROSS-REFERENCE TO RELATED APPLICATION

The present application claims priority under 35 U.S.C. § 119(a) to Korean patent application number 10-2020-0072564 filed on Jun. 15, 2020, in the Korean Intellectual Property Office, the entire disclosure of which is incorporated by reference herein.

### BACKGROUND

### 1. Technical Field

The present disclosure generally relates to a semiconductor device and a manufacturing method of the semiconductor device, and more particularly, to a three-dimensional semiconductor device and a manufacturing method of the three-dimensional semiconductor device.

### 2. Related Art

A nonvolatile memory device is a memory device in which stored data is maintained even when the supply of power is interrupted. As the improvement of the degree of integration of two-dimensional nonvolatile memory devices with memory cells that are formed over a semiconductor substrate in the form of a single layer has reached its limit, three-dimensional nonvolatile memory devices in which memory cells are formed in a vertical direction over a semiconductor substrate have been proposed.

The three-dimensional memory device includes interlayer insulating layers and gate electrodes, alternately stacked, and channel layers that penetrate the interlayer insulating layers and the gate electrodes, and memory cells that are stacked along the channel layers. Various structures and manufacturing methods have been developed to improve the operational reliability of the three-dimensional nonvolatile memory device.

### SUMMARY

In accordance with an aspect of the present disclosure, there is provided a semiconductor device including: a first stack structure with first insulating patterns and first conductive patterns, alternately stacked, the first stack structure with a first stepped structure that is defined by the first insulating patterns and the first conductive patterns; a second stack structure with second insulating patterns and second conductive patterns, alternately stacked on the first stack structure; and a first protrusion stack structure protruding laterally toward the first stepped structure from the second stack structure, the first protrusion stack structure with first protrusion insulating patterns and first protrusion conductive patterns, alternately stacked on the first stack structure, wherein a sidewall of the first protrusion stack structure includes side surfaces of the first protrusion insulating patterns and side surfaces of the first protrusion conductive patterns, which form a common surface.

In accordance with another aspect of the present disclosure, there is provided a semiconductor device including: a first stack structure with first insulating patterns and first conductive patterns, alternately stacked, the first stack structure with a first stepped structure that is defined by the first insulating patterns and the first conductive patterns; a second stack structure with second insulating patterns and second conductive patterns, alternately stacked, the second stack structure with a second stepped structure that is defined by the second insulating patterns and the second conductive patterns; a third stack structure with third insulating patterns and third conductive patterns, alternately stacked on the first stack structure; a fourth stack structure with fourth insulating patterns and fourth conductive patterns, alternately stacked on the second stack structure; and an insulating part that is filled between the first and second stack structures and between the third and fourth stack structures, wherein an upper portion of the insulating part includes first parts and a second part, the second part with a width that is smaller than a width of the first parts.

In accordance with still another aspect of the present disclosure, there is provided a semiconductor device including: a first stack structure with first insulating patterns and first conductive patterns, alternately stacked, the first stack structure with first stepped structures that is defined by the first insulating patterns and the first conductive patterns; and a first isolation stack structure disposed on the first stepped structures, the first isolation stack structure with first isolation insulating patterns and first isolation conductive patterns, alternately stacked, wherein the first isolation stack structure includes a second stepped structure defined by the first isolation insulating patterns and the first isolation conductive patterns, and wherein the second stepped structure is disposed at a higher level than a level of the first stepped structures.

In accordance with still another aspect of the present disclosure, there is provided a method of manufacturing a semiconductor device, the method including: forming a first preliminary stack structure with first preliminary insulating layers and first preliminary sacrificial layers; forming, on the first preliminary stack structure, a second preliminary stack structure with second preliminary insulating layers and second preliminary sacrificial layers; forming a third preliminary stack structure with a first stepped structure by etching the second preliminary stack structure; forming a first mask pattern on the third preliminary stack structure; and etching the third preliminary stack structure and the first preliminary stack structure by using the first mask pattern as an etching barrier, wherein the first mask pattern includes a first part and a second part, the second part protruding toward the first stepped structure from the first part, and wherein a width of the second part is smaller than a width of the first part.

In accordance with still another aspect of the present disclosure, there is provided a method of manufacturing a semiconductor device, the method including: forming a first preliminary stack structure; forming a second preliminary stack structure on the first preliminary stack structure; forming a first space by etching the first and second preliminary stack structures; and forming an insulating part filling the first space, wherein an upper portion of the insulating part includes first parts and a second part between the first parts, and wherein a width of the second part is smaller than a width of the first parts.

In accordance with still another aspect of the present disclosure, there is provided a method of manufacturing a semiconductor device, the method including: forming a first preliminary stack structure; forming a second preliminary stack structure on the first preliminary stack structure; forming a third preliminary stack structure with a first stepped structure and a fourth preliminary stack structure with a second stepped structure by etching the first and second preliminary stack structures; forming a mask pattern covering a portion of the second stepped structure; and etching the third preliminary stack structure and the fourth preliminary stack structure by using the mask pattern as an etching barrier.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1A is a perspective view of a semiconductor device in accordance with an embodiment of the present disclosure.

FIG. 1B is a plan view of the semiconductor device as shown in FIG. 1A.

FIG. 1C is a sectional view that is taken along line A-A′ as shown in FIG. 1B.

FIG. 1D is a sectional view that is taken along line B-B′ as shown in FIG. 1B.

FIGS. 1E and 1F are perspective views, illustrating a second insulating layer of the semiconductor device, shown in FIGS. 1A, 1B, 1C, and 1D.

FIGS. 2A, 2B, 2C, 2D, and 2E are perspective views, illustrating a manufacturing method of the semiconductor device, shown in FIGS. 1A, 1B, 1C, and 1D.

FIG. 3 is a perspective view of a semiconductor device in accordance with an embodiment of the present disclosure.

FIG. 4 is a perspective view of a semiconductor device in accordance with an embodiment of the present disclosure.

FIG. 5A is a perspective view of a semiconductor device in accordance with an embodiment of the present disclosure.

FIG. 5B is a perspective view, illustrating an isolation stack structure, shown in FIG. 5A.

FIGS. 6A, 6B, 6C, and 6D are perspective views, illustrating a manufacturing method of the semiconductor device, shown in FIGS. 5A and 5B.

FIG. 7 is a block diagram, illustrating a configuration of a memory system in accordance with an embodiment of the present disclosure.

FIG. 8 is a block diagram, illustrating a configuration of a computing system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

It will be understood that although the terms “first”, “second”, “third” etc. are used herein to describe various elements, these elements should not be limited by these terms. These terms are only used to distinguish one element from another element. Thus, a first element in some embodiments could be termed a second element in other embodiments without departing from the teachings of the present disclosure.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Embodiments provide a semiconductor device capable of improving structural stability and a manufacturing method of the semiconductor device.

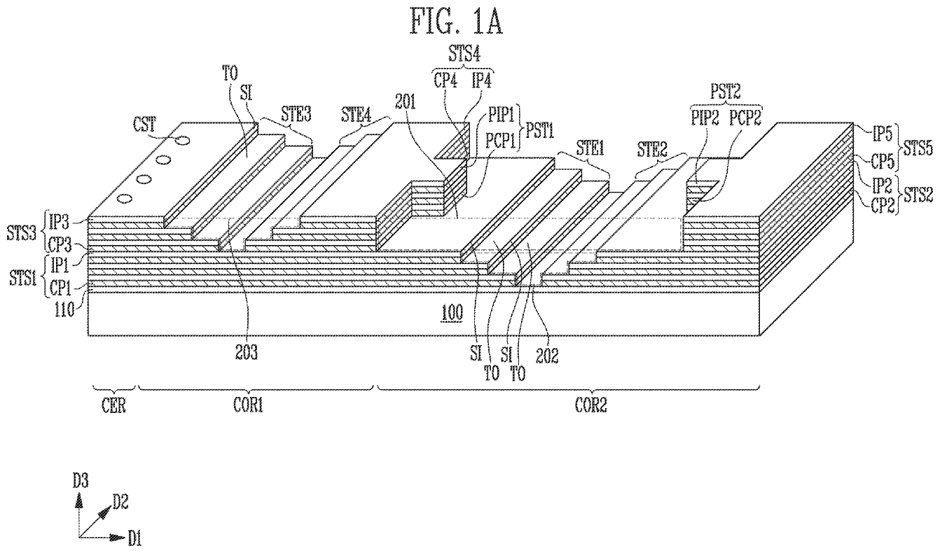

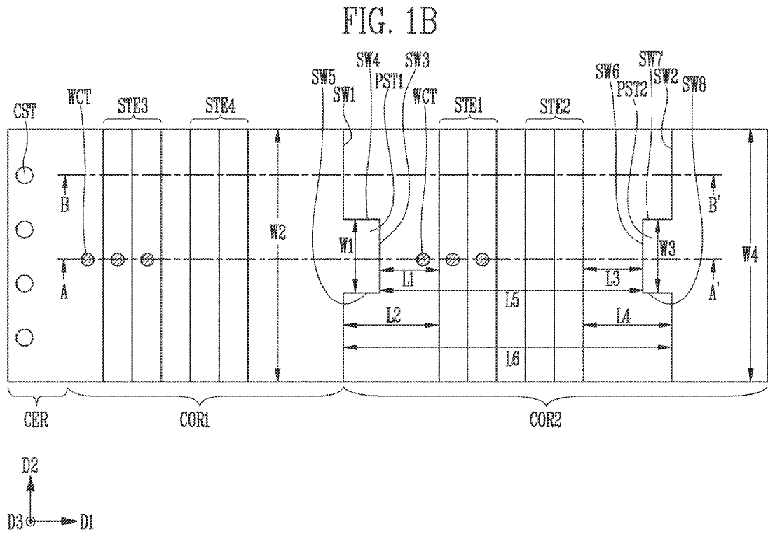

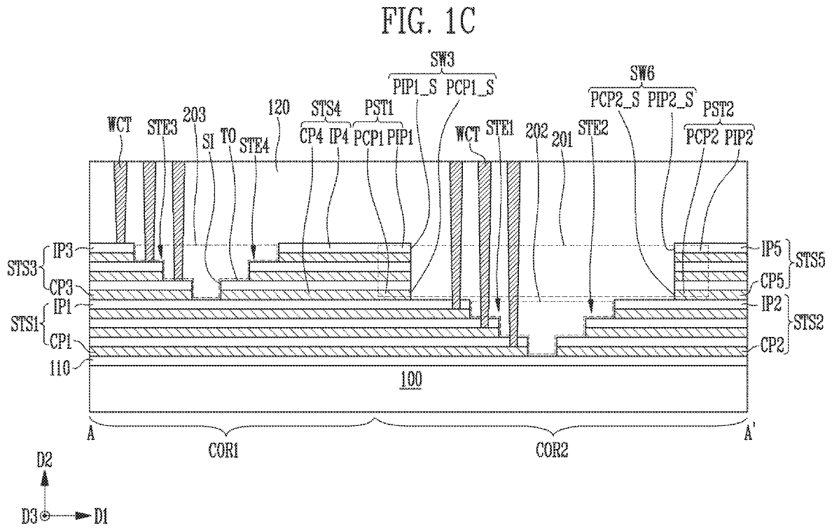

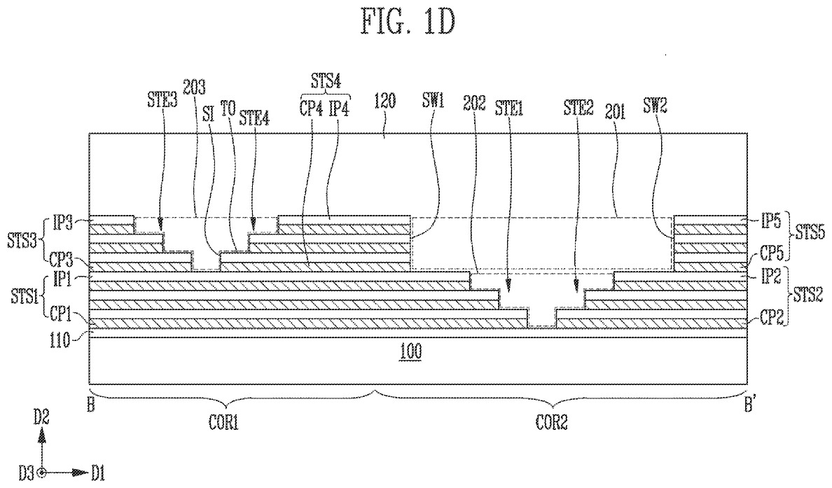

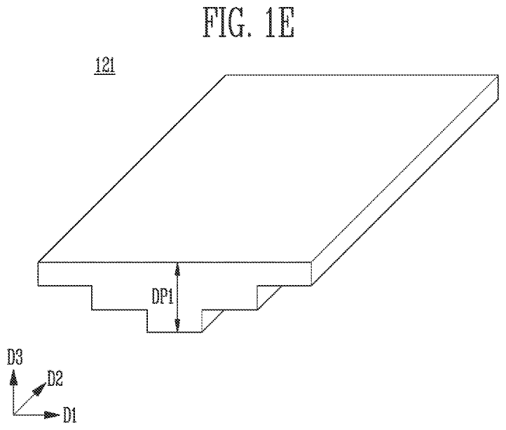

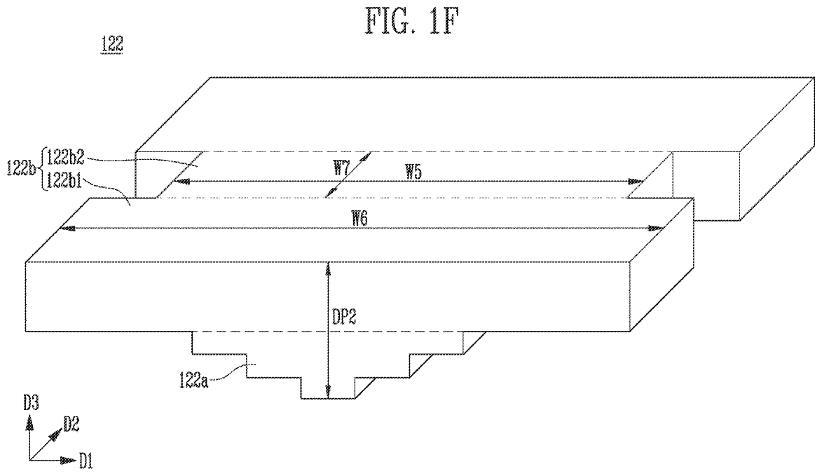

FIG. 1A is a perspective view of a semiconductor device in accordance with an embodiment of the present disclosure. FIG. 1B is a plan view of the semiconductor device as shown in FIG. 1A. FIG. 1C is a sectional view that is taken along line A-A′ as shown in FIG. 1B. FIG. 1D is a sectional view that is taken along line B-B′ as shown in FIG. 1B.

Referring to FIGS. 1A, 1B, 1C, and 1D, the semiconductor device may include a base part 100. The base part 100 may have the shape of a plate that expands along a plane that is defined by a first direction D1 and a second direction D2. The first direction D1 and the second direction D2 may intersect each other. In an example, the first direction D1 and the second direction D2 may be orthogonal.

In an example, the base part 100 may include a source structure. The source structure may be used as a source line that is connected to a memory cell. The source structure may include a semiconductor material. In an example, the source structure may include poly-silicon.

A first insulating layer 110 may be provided on the base part 100. The first insulating layer 110 may have the shape of a plate that expands along a plane that is defined by the first direction D1 and the second direction D2. The first insulating layer 110 may include an insulating material.

The semiconductor device may include a cell region CER, a first connection region COR1, and a second connection region COR2. The cell region CER, a first connection region COR1, and the second connection region COR2 may be regions that are distinguished from each other on a plane. Cell structures CST may be disposed in the cell region CER. Word line contacts WCT may be disposed in the first connection region COR1 and the second connection region COR2. The word line contact WCT may be connected to conductive patterns CP1 and CP3, which control the cell structures CST.

The cell region CER, a first connection region COR1, and the second connection region COR2 may be sequentially arranged in the first direction DR1. The cell region CER and the first connection region COR1 may be connected to each other, and the first connection region COR1 and the second connection region COR2 may be connected to each other. The first connection region COR1 may be disposed between the cell region CER and the second connection region COR2.

A first stack structure STS1 may be provided on the first insulating layer 110. The first stack structure STS1 may include first conductive patterns CP1 and first insulating patterns IP1, alternately stacked in a third direction D3. The third direction D3 may intersect the first direction D1 and the second direction D2. In an example, the third direction D3 may be orthogonal to the first direction D1 and the second direction D2.

The first insulating patterns IP1 may include an insulating material. In an example, the first insulating patterns IP1 may include oxide. The first conductive patterns CP1 may include a conductive layer. The conductive layer may include a conductive material. In an example, the conductive layer may include at least one of a doped silicon layer, a metal silicide layer, tungsten, nickel, and cobalt. The conductive layer may be used as a word line that is connected to a memory cell or a select line that is connected to a select transistor. The first conductive patterns CP1 may further include a barrier layer that surrounds the conductive layer. In an example, the barrier layer may include at least one of titanium nitride and a tantalum nitride.

The first stack structure STS1 may extend up to the second connection region COR2 via the cell region CER and the first connection region COR1. In other words, the first stack structure STS1 may include a part that is disposed in the cell region CER, a part that is disposed in the first connection region COR1, and a part that is disposed in the second connection region COR2.

The first stack structure STS1 may include a first stepped structure STE1. The first stepped structure STE1 may be defined by the first insulating patterns IP1 and the first conductive patterns CP1. The first insulating patterns IP1 and the first conductive patterns CP1 of the first stack structure STS1 may be formed in a stepped shape to form the first stepped structure STE1. The first stepped structure STE1 may be disposed in the second connection region COR2.

In an embodiment, as shown in the drawings, a portion of a top surface of the first insulating pattern IP1 between the conductive patterns CP1 may be defined as a step top surface TO. A portion of a top surface of the first insulating pattern IP1, which is not covered by the first conductive pattern CP1, may be defined as a step top surface TO. The step top surfaces TO may extend in the second direction D2. The width of the step top surface TO in the second direction D2 may be greater than the width of the step top surface TO in the first direction D1.

In another embodiment, unlike the drawings, a portion of a top surface of the first conductive pattern CP1, which is not covered by the first insulating pattern IP1, may be defined as a step top surface.

Step side surfaces SI may be connected to the step top surface TO at both sides of the step top surface TO. One step side surface SI may include a side surface of one first insulating pattern IP1 and a side surface of one first conductive pattern CP1, which form a common surface. The step side surfaces SI may extend in the second direction D2. The width of the step side surface SI in the second direction D2 may be greater than the height of the step side surface SI in the third direction D3. The step side surfaces SI may be perpendicular to the first direction D1.

The surface of the first stepped structure STE1 may be defined by the step top surfaces TO and the step side surfaces SI. Each of the step side surfaces SI of the first stepped structure STE1 may be disposed at a lower level as the step side surface SI is disposed farther away from the cell structures CST in the first direction D1. Each of the step top surfaces TO of the first stepped structure STE1 may be disposed at a lower level as the step top surface TO is disposed farther away from the cell structures CST in the first direction D1.

A second stack structure STS2 may be provided on the first insulating layer 110. The second stack structure STS2 may include second conductive patterns CP2 and second insulating patterns IP2, alternately stacked in the third direction D3. The second insulating patterns IP2 may include an insulating material. The second conductive patterns CP2 may include a conductive layer. The second conductive patterns CP2 may further include a barrier layer that surrounds the conductive layer.

The second stack structure STS2 may be disposed in the second connection region COR2. The second stack structure STS2 may be disposed from the first stack structure STS1 in the first direction D1. The second stack structure STS2 may be disposed at the same level as the first stack structure STS1.

The second stack structure STS2 may include a second stepped structure STE2. The second stepped structure STE2 may be defined by the second insulating patterns IP2 and the second conductive patterns CP2. The second insulating patterns IP2 and the second conductive patterns CP2 of the second stack structure STS2 may be formed in a stepped shape to form the second stepped structure STE2. The second stepped structure STE2 may be disposed in the second connection region COR2.

Similarly to the first stepped structure STE1, the second stepped structure STE2 may include step top surfaces TO and step side surfaces SI. The surface of the second stepped structure STE2 may be defined by the step top surfaces TO and the step side surfaces SI. The step top surfaces TO and the step side surfaces SI of the second stepped structure STE2 may extend in the second direction D2.

The second stepped structure STE2 may face the first stepped structure STE1. The second stepped structure STE2 and the first stepped structure STE1 may have a structure in which the second stepped structure STE2 and the first stepped structure STE1 are symmetrical with respect to a space between the first and second stepped structures STE1 and STE2. Each of the step side surfaces SI of the second stepped structure STE2 may be disposed at a higher level as the step side surface SI is disposed farther away from the cell structures CST in the first direction D1. Each of the step top surfaces TO of the second stepped structure STE2 may be disposed at a higher level as the step top surface TO is disposed farther away from the cell structures CST in the first direction D1. The second stepped structure STE2 may be disposed at the same level as the first stepped structure STE1.

A third stack structure STS3 may be provided on the first stack structure STS1. The third stack structure STS3 may be provided on the first insulating pattern IP1 at an uppermost portion of the first stack structure STS1. The third stack structure STS3 may include third conductive patterns CP3 and third insulating patterns IP3, alternately stacked in the third direction D3. The third insulating patterns IP3 may include an insulating material. The third conductive patterns CP3 may include a conductive layer. The third conductive patterns CP3 may further include a barrier layer that surrounds the conductive layer.

The third stack structure STS3 may extend up to the first connection region COR1 from the cell region CER. In other words, the third stack structure STS3 may include a part that is disposed in the cell region CER and a part that is disposed in the first connection region COR1.

The third stack structure STS3 may include a third stepped structure STE3. The third stepped structure STE3 may be defined by the third insulating patterns IP3 and the third conductive patterns CP3. The third insulating patterns IP3 and the third conductive patterns CP3 of the third stack structure STS3 may be formed in a stepped shape to form the third stepped structure STE3. The third stepped structure STE3 may be disposed in the first connection region COR1.

Similarly to the first and second stepped structures STE1 and STE2, the third stepped structure STE3 may include step top surfaces TO and step side surfaces SI. The surface of the third stepped structure STE3 may be defined by the step top surfaces TO and the step side surfaces SI. The step top surfaces TO and the step side surfaces SI of the third stepped structure STE3 may extend in the second direction D2.

Each of the step side surfaces SI of the third stepped structure STE3 may be disposed at a lower level as the step side surface SI is disposed farther away from the cell structures CST in the first direction D1. Each of the step top surfaces TO of the third stepped structure STE3 may be disposed at a lower level as the step top surface TO is disposed farther away from the cell structures CST in the first direction D1. The third stepped structure STE3 may be disposed at a higher level than the level of the first and second stepped structures STE1 and STE2.

A fourth stack structure STS4 may be provided on the first stack structure STS1. The fourth stack structure STS4 may be provided on the first insulating pattern IP1 at the uppermost portion of the first stack structure STS1. The fourth stack structure STS4 may include fourth conductive patterns CP4 and fourth insulating patterns IP4, alternately stacked in the third direction D3. The fourth insulating patterns IP4 may include an insulating material. The fourth conductive patterns CP4 may include a conductive layer. The fourth conductive patterns CP4 may further include a barrier layer that surrounds the conductive layer.

The fourth stack structure STS4 may be disposed in the first connection region COR1. The fourth stack structure STS4 may be spaced apart from the third stack structure STS3 in the first direction D1.

The fourth stack structure STS4 may include a fourth stepped structure STE4. The fourth stepped structure STS4 may be defined by the fourth insulating patterns IP4 and the fourth conductive patterns CP4. The fourth insulating patterns IP4 and the fourth conductive patterns CP4 of the fourth stack structure STS4 may be formed in a stepped shape to form the fourth stepped structure STE4. The fourth stepped structure STE4 may be disposed in the first connection region COR1.

Similarly to the first to third stepped structures STE1, STE2, and STE3, the fourth stepped structure STE4 may include step top surfaces TO and step side surfaces SI. The surface of the fourth stepped structure STE4 may be defined by the step top surfaces TO and the step side surfaces SI. The step top surfaces TO and the step side surfaces SI of the fourth stepped structure STE4 may extend in the second direction D2.

The fourth stepped structure STE4 may face the third stepped structure STE3. The fourth stepped structure STE4 and the third stepped structure STE3 may have a structure in which the fourth stepped structure STE4 and the third stepped structure STE3 are symmetrical with respect to a space between the third and fourth stepped structures STE3 and STE4. Each of the step side surfaces SI of the fourth stepped structure STE4 may be disposed at a higher level as the step side surface SI is disposed farther away from the cell structures CST in the first direction D1. Each of the step top surfaces TO of the fourth stepped structure STE4 may be disposed at a higher level as the step top surface TO is disposed farther away from the cell structures CST in the first direction D1. The fourth stepped structure STE4 may be disposed at the same level as the third stepped structure STE3.

The fourth stack structure STS4 may include a first sidewall SW1. The first sidewall SW1 may be a sidewall that is located in the opposite direction of the fourth stepped structure STE4. The first sidewall SW1 may be defined by side surfaces of the fourth insulating patterns IP4 and side surfaces of the fourth conductive patterns CP4. The first sidewall SW1 may be defined by the side surfaces of the fourth insulating patterns IP4 and the side surfaces of the fourth conductive patterns CP4, which form a common surface. The first sidewall SW1 may extend in the second direction D2. The first sidewall SW1 may extend in the second direction D2. The first sidewall SW1 may be perpendicular to the first direction D1. The first sidewall SW1 may be a sidewall of the fourth stack structure STS4 that is adjacent to the first stepped structure STE1.

A fifth stack structure STS5 may be provided on the second stack structure STS2. The fifth stack structure STS5 may be provided on the second insulating pattern IP2 at an uppermost portion of the second stack structure STS2. The fifth stack structure STS5 may include five conductive patterns CP5 and fifth insulating patterns IP5, alternately stacked in the third direction D3. The fifth insulating pattern IP5 may include an insulating material. The fifth conductive patterns CP5 may include a conductive layer. The fifth conductive pattern CP5 may further include a barrier layer that surrounds the conductive layer.

The fifth stack structure STS5 may be disposed in the second connection region COR2. The fifth stack structure STS5 may be spaced apart from the fourth stack structure STS4 in the first direction D1. The fifth stack structures STS5 may include a second sidewall SW2. The second sidewall SW2 may face the first sidewall SW1 of the fourth stack structure STS4. The second sidewall SW2 may be defined by side surfaces of the fifth insulating patterns IP5 and side surfaces of the fifth conductive patterns CP5. The second sidewall SW2 may be defined by the side surfaces of the fifth insulating patterns IP5 and the side surfaces of the fifth conductive patterns CP5, which form a common surface. The second sidewall SW2 may extend in the second direction D2. The second sidewall SW2 may be perpendicular to the first direction D1. The second sidewall SW2 may be a sidewall of the fifth stack structure STS5, which is adjacent to the second stepped structure STE2.

A first protrusion stack structure PST1 may be provided on the first stack structure STS1. The first protrusion stack structure PST1 may be provided on the first insulating pattern IP1 at the uppermost portion of the first stack structure STS1. The first protrusion stack structure PST1 may include a plurality of first protrusion conductive patterns PCP1 and a plurality of first protrusion insulating patterns PIP1, alternately stacked in the third direction D3. The first protrusion insulating patterns PIP1 may include an insulating material. The first protrusion conductive patterns PCP1 may include a conductive layer. The first protrusion conductive patterns PCP1 may further include a barrier layer that surrounds the conductive layer.

The first protrusion insulating patterns PIP1 and the first protrusion conductive patterns PCP1 may completely overlap with each other. The first protrusion insulating patterns PIP1 and the first protrusion conductive patterns PCP1 may have the same planar area. The first protrusion insulating patterns PIP1 and the first protrusion conductive patterns PCP1 may have the same planar shape and the same planar position.

The first protrusion stack structure PST1 may be connected to the fourth stack structure STS4. The first protrusion stack structure PST1 may be connected to the first sidewall SW1 of the fourth stack structure STS4. The first protrusion stack structure PST1 may protrude toward the first stepped structure STE1 from the first sidewall SW1 of the fourth stack structure STS4. The first protrusion stack structure PST1 may protrude in the first direction D1 from the first sidewall SW1 of the fourth stack structure STS4.

The first protrusion stack structure PST1 and the fourth stack structure STS4 may be continuously formed without any boundary. The first protrusion conductive patterns PCP1 of the first protrusion stack structure PST1 and the fourth conductive pattern CP4 of the fourth stack structure STS4 may be continuously formed without any boundary. The first protrusion insulating patterns PIP1 of the first protrusion stack structure PST1 and the fourth insulating patterns IP4 of the fourth stack structure STS4 may be continuously formed without any boundary.

The first protrusion stack structure PST1 may be disposed at the same level as the fourth stack structure STS4. The first protrusion conductive patterns PCP1 of the first protrusion stack structure PST1 may be disposed at the same levels as the fourth conductive patterns CP4 of the fourth stack structure STS4. The first protrusion insulating patterns PIP1 of the first protrusion stack structure PST1 may be disposed at the same levels as the fourth insulating patterns IP4 of the fourth stack structure STS4.

The number of first protrusion conductive patterns PCP1 of the first protrusion stack structure PST1 may be equal to the number of fourth conductive patterns CP4 of the fourth stack structure STS4. The number of first protrusion insulating patterns PIP1 of the first protrusion stack structure PST1 may be equal to the number of fourth insulating patterns IP4 of the fourth stack structure STS4.

The width of the first protrusion stack structure PST1 may be smaller than the width of the fourth stack structure STS4. The width of the first protrusion stack structure PST4 in the second direction D2 may be defined as a first width W1. The width of the fourth stack structure STS4 may be defined by a second width W2. The width W1 may be smaller than the second width W2.

The first protrusion stack structure PST1 may be spaced apart from the first stepped structure STE1. The shortest distance between the first protrusion stack structure PST1 and the first stepped structure STE1 may be defined as a first distance L1. The first distance L1 may be a distance between the first protrusion stack structure PST1 and the first stepped structure STE1 in the first direction D1. The fourth stack structure STS4 may be spaced apart from the first stepped structure STE1. The shortest distance between the fourth stack structure STS4 and the first stepped structure STE1 may be defined as a second distance L2. The second distance L2 may be a distance between the fourth stack structure STS4 and the first stepped structure STE1 in the first direction D1. The second distance L2 may be the shortest distance between the first sidewall SW1 and the first stepped structure STE1 of the first stack structure STS1. The first distance L1 may be smaller than the second distance L2.

The first protrusion stack structure PST1 may include a third sidewall SW3, a fourth sidewall SW4, and a fifth sidewall SW5. The third sidewall SW3 may be parallel to the first sidewall SW1 of the fourth stack structure STS4. The fourth sidewall SW4 may connect the first sidewall SW1 of the fourth stack structure STS4 and the third sidewall SW3. The fifth sidewall SW5 may connect the first sidewall SW1 of the fourth stack structure STS4 and the third sidewall SW3. The third sidewall SW3 may be a sidewall of the first protrusion stack structure PST1, which is adjacent to the first stepped structure STE1.

The first distance L1 may be the shortest distance between the third sidewall SW3 and the first stepped structure STE1 of the first stack structure STS1. The first width W1 may be a distance between the fourth sidewall SW4 and the fifth sidewall SW5.

Each of the third to fifth sidewalls SW3, SW4, and SW5 of the first protrusion stack structure PST1 may include side surfaces PCP1_S of the plurality of first protrusion conductive patterns PCP1 and side surfaces PIP1_S of the plurality of first protrusion insulating patterns PIP1, which form a common surface. Each of the third to fifth sidewalls SW3, SW4, and SW5 of the first protrusion stack structure PST1 may be flat.

A portion that is adjacent to the first stepped structure STE1 in the top surface of the first insulating pattern IP1 at the uppermost portion of the first stack structure STS1 might not be covered by the fourth stack structure STS4 and the first protrusion stack structure PST1. In other words, a portion of the top surface of the first insulating pattern IP1 at the uppermost portion of the first stack structure STS1 may be exposed between the first stepped structure STE1 and the first protrusion stack structure PST1 and between the first stepped structure STE1 and fourth stack structure STS4.

A second protrusion stack structure PST2 may be provided on the second stack structure STS2. The second protrusion stack structure PST2 may be provided on the second insulating pattern IP2 at the uppermost portion of the second stack structure STS2. The second protrusion stack structure PST2 may include a plurality of second protrusion conductive patterns PCT2 and a plurality of second protrusion insulating patterns PIP2, alternately stacked in the third direction D3. The second protrusion insulating patterns PIP2 may include an insulating material. The second protrusion conductive patterns PCT2 may include a conductive layer. The second protrusion conductive patterns PCT2 may further include a barrier layer that surrounds the conductive layer.

The second protrusion insulating patterns PIP2 and the second protrusion conductive patterns PCP2 may completely overlap with each other. The second protrusion insulating patterns PIP2 and the second protrusion conductive patterns PCP2 may have the same planar area. The second protrusion insulating patterns PIP2 and the second protrusion conductive patterns PCP2 may have the same planar shape and the same planar position.

The second protrusion stack structure PST2 may be connected to the fifth stack structure STS5. The second protrusion stack structure PST2 may be connected to the second sidewall SW2 of the fifth stack structure STS5. The second protrusion stack structure PST2 may protrude toward the second stepped structure STE2 from the second sidewall SW2 of the fifth stack structure STS5. The second protrusion stack structure PST2 may protrude in the opposite direction of the first direction D1 from the second sidewall SW2 of the fifth stack structure STS5.

The second protrusion stack structure PST2 and the fifth stack structure STS5 may be continuously formed without any boundary. The second protrusion conductive patterns PCP2 of the second protrusion stack structure PST2 and the fifth conductive patterns CP5 of the fifth stack structure STS5 may be continuously formed without any boundary. The second protrusion insulating patterns PIP2 of the second protrusion stack structure PST2 and the fifth insulating patterns IP5 of the fifth stack structure STS5 may be continuously formed without any boundary.

The second protrusion stack structure PST2 may be disposed at the same level as the fifth stack structure STS5. The second protrusion conductive patterns PCP2 of the second protrusion stack structure PST2 may be disposed at the same levels as the fifth conductive patterns CP5 of the fifth stack structure STS5. The second protrusion insulating patterns PIP2 of the second protrusion stack structure PST2 may be disposed at the same levels as the fifth insulating patterns IP5 of the fifth stack structure STS5.

The number of second protrusion conductive patterns PCP2 of the second protrusion stack structure PST2 may be equal to the number of fifth conductive patterns CP5 of the fifth stack structure STS5. The number of second protrusion insulating patterns PIP2 of the second protrusion stack structure PST2 may be equal to the number of fifth insulating patterns IP5 of the fifth stack structure STS5.

The width of the second protrusion stack structure PST2 may be smaller than that of the fifth stack structure STS5. The width of the second protrusion stack structure PST2 in the second direction D2 may be defined as a third width W3. The width of the fifth stack structure STS5 in the second direction D2 may be defined as a fourth width W4. The third width W3 may be smaller than the fourth width W4.

The second protrusion stack structure PST2 may be spaced apart from the second stepped structure STE2. The shortest distance between the second protrusion stack structure PST2 and the second stepped structure STE2 may be defined as a third distance L3. The third distance L3 may be a distance between the second protrusion stack structure PST2 and the second stepped structure STE2 in the first direction D1. The fifth stack structure STS5 may be spaced apart from the second stepped structure STE2. The shortest distance between the fifth stack structure STS5 and the second stepped structure STE2 may be defined as a fourth distance L4. The fourth distance L4 may be a distance between the fifth stack structure STS5 and the second stepped structure STE2 in the first direction D1. The fourth distance L4 may be the shortest distance between the second sidewall SW2 and the second stepped structure STE2 of the second stack structure STS2. The third distance L3 may be smaller than the fourth distance L4.

The second protrusion stack structure PST2 may include a sixth sidewall SW6, a seventh sidewall SW7, and an eighth sidewall SW8. The sixth sidewall SW6 may be parallel to the second sidewall SW2 of the fifth stack structure STS5. The seventh sidewall SW7 may connect the second sidewall SW2 of the fifth stack structure STS5 and the sixth sidewall SW6. The eighth sidewall SW8 may connect the second sidewall SW2 of the fifth stack structure STS5 and the sixth sidewall SW6. The sixth sidewall SW6 may be a sidewall of the second protrusion stack structure PST2, which is adjacent to the second stepped structure STE2.

The third distance L3 may be the shortest distance between the sixth sidewall SW6 and the second stepped structure STE2 of the second stack structure STS2. The third width W3 may be the distance between the seventh sidewall SW7 and the eighth sidewall SW8.

Each of the sixth to eighth sidewalls SW6, SW7, and SW8 of the second protrusion stack structure PST2 may include side surfaces PCP2_S of the plurality of second protrusion conductive patterns PCP2 and side surfaces PIP2_S of the plurality of second protrusion insulating patterns PIP2, which form a common surface. Each of the sixth to eighth sidewalls SW6, SW7, and SW8 of the second protrusion stack structure PST2 may be flat.

A portion that is adjacent to the second stepped structure STE2 in the top surface of the second insulating pattern IP2 at the uppermost portion of the second stack structure STS2 might not be covered by the fifth stack structure STS5 and the second protrusion stack structure PST2. In other words, the portion of the top surface of the second insulating pattern IP2 at the uppermost portion of the second stack structure STS2 may be exposed between the second stepped stack structure STE2 and the second protrusion stack structure PST2 and between the second stepped stack structure STE2 and the fifth stack structure STS5.

The shortest distance between the first protrusion stack structure PST1 and the second protrusion stack structure PST2 may be defined as a fifth distance L5. The fifth distance L5 may be the shortest distance between the third sidewall SW3 of the first protrusion stack structure PST1 and the sixth sidewall SW6 of the second protrusion stack structure PST2. The shortest distance between the fourth stack structure STS4 and the fifth stack structure STS5 may be defined as a sixth distance L6. The sixth distance L6 may be the shortest distance between the first sidewall SW1 of the fourth stack structure STS4 and the second sidewall SW2 of the fifth stack structure STS5. The fifth distance L5 may be smaller than the sixth distance L6.

The fourth and fifth stack structures STS4 and STS5 may be spaced apart from each other in the first direction D1, and a first space 201 (see FIGS. 1C and 1D) between the fourth and fifth stack structures STS4 and STS5 may be provided. The first space 201 may be defined as a space that is located at the same level as the fourth and fifth stack structures STS4 and STS5.

A space between the first and second stack structures STS1 and STS2 may be defined as a second space 202. The second space 202 may be defined as a space that is located at the same level as the first and second stack structures STS1 and STS2. The second space 202 may be a space that is defined between the first and second stepped structures STE1 and STE2.

The space between the third and fourth stack structures STS3 and STS4 may be defined as a third space 203. The third space 203 may be defined as a space that is located at the same level as the third and fourth stack structures STS3 and STS4. The third space 203 may be a space that is defined between the third and fourth stepped structures STE3 and STE4.

The first and second protrusion stack structures PST1 and PST2 may be disposed between the fourth and fifth stack structures STS4 and STS5. The first and second protrusion stack structures PST1 and PST2 may be disposed in the first space 201 between the fourth and fifth stack structures STS4 and STS5. The first and second protrusion stack structures PST1 and PST2 may protrude toward the first space 201 respectively from the fourth and fifth stack structures STS4 and STS5. Because the first and second protrusion stack structures PST1 and PST2 are formed, the first space 201 between the fourth and fifth stack structures STS4 and STS5 may be partially narrow.

The cell structures CST may be provided, which penetrate the first stack structure STS1, the third stack structure STS3, and the first insulating layer 110 of the cell region CER. The cell structures CST may penetrate the first insulating patterns IP1 and the first conductive patterns CP1 of the first stack structure STS1 and the third insulating layers IP3 and the third conductive patterns CP3 of the third stack structure STS3. The cell structures CST may extend in the third direction D3.

Each of the cell structures CST may include a channel layer penetrating the first and third stack structures STS1 and STS3 and a memory layer that surrounds the channel layer. The channel layer may include a semiconductor material. In an example, the channel layer may include poly-silicon. The channel layer may be electrically connected to the source structure of the base part 100.

The memory layer may include multi-layered insulating layers. The memory layer may include a tunnel insulating layer that surrounds the channel layer, a storage layer that surrounds the tunnel insulating layer, and a blocking layer that surrounds the storage layer. The tunnel insulating layer may include an insulating material through which charges can tunnel. In an example, the tunnel insulating layer may include oxide. The storage layer may include a material in which charges can be trapped. The material which the storage layer includes is not limited to nitride, and may be variously changed depending a data storage method. In an example, the storage layer may include one of silicon, a phase change material, and nano dots. The blocking layer may include an insulating material capable of blocking movement of charges. In an example, the blocking layer may include oxide.

In an embodiment, the cell structure may further include a filling layer in the channel layer. The filling layer may include an insulating material. The filling layer may include oxide.

A second insulating layer 120 may be provided, which covers the first to fifth stack structures STS1, STS2, STS3, STS4, and STS5 and the first and second protrusion stack structures PST1 and PST2. The second insulating layer 120 may insulate the word line contacts WCT from each other. The second insulating layer 120 may fill the first space 201, the second space 202, and the third space 203. The second insulating layer 120 may include an insulating material. In an example, the second insulating layer 120 may include oxide.

The word line contacts WCT may penetrate the second insulating layer 120. The word line contacts WCT may be respectively connected to the third conductive patterns CP3 of the third stack structures STS3 or the first conductive patterns CP1 of the first stack structure STS1. The word line contacts WCT may be disposed in the first connection region COR1 or the second connection region COR2.

The first contact patterns CP1 of the first stack structure STS1, which are connected to the word line contacts WCT, may surround the cell plugs CST. The third contact patterns CP3 of the third stack structure STS3, which are connected to the word line contacts WCT, may surround the cell plugs CST.

In the semiconductor device, in accordance with this embodiment, the depth of the space that is formed by connecting the first space 201 and the second space 202 may be relatively deeper than the depth of the third space 203. Accordingly, it may be highly likely that a void will be formed at a portion that fills the first space 201 and the second space 202.

The semiconductor device includes the first and second protrusion stack structures PST1 and PST2, so that the first space 201 between the fourth and fifth stack structures STS4 and STS5 can be formed to be partially narrow. Accordingly, when the first space 201 between the fourth and fifth stack structures STS4 and STS5 and the second space 202 between the first and second stepped structures STE1 and STE2 are filled with the second insulating layer 120, any void can be suppressed from being formed in the second insulating layer 120, and the structural stability of the semiconductor device can be improved.

FIGS. 1E and 1F are perspective views, illustrating the second insulating layer of the semiconductor device, shown in FIGS. 1A, 1B, 1C, and 1D. For convenience of description, components that are identical to those described with reference to FIGS. 1A, 1B, 1C, and 1D are designated by like reference numerals, and their overlapping descriptions will be omitted.

Referring to FIG. 1E, the second insulating layer 120 may include a first insulating part 121 filling the third space 203. The bottom surface of the first insulating part 121 may have a shape that corresponds to the surface of the third and fourth stepped structures STE3 and STE4. The bottom surface of the first insulating part 121 may be formed in a stepped shape.

The deepest depth of the first insulating part 121 may be defined as a first depth DP1.

Referring to FIG. 1F, the second insulating layer 120 may include a second insulating part 122 filling the first and second spaces 201 and 202. The second insulating part 122 may include a lower portion 122a and an upper portion 122b. The lower portion 122a may be portion filling the second space 202. The upper portion 122b may be a portion filling the first space 201.

The bottom surface of the lower portion 122a may have a shape that corresponds to the surface of the first and second stepped structures STE1 and STE2. The bottom surface of the lower portion 122a may be formed in a stepped shape.

The upper portion 122b may include first parts 122b1 and a second part 122b2. The first part 122b1 may be a part provided between the first sidewall SW1 of the fourth stack structure STS4 and the second sidewall SW2 of the fifth stack structure STS5. The second part 122b2 may be a part provided between the third sidewall SW3 of the first protrusion stack structure PST1 and the sixth sidewall SW6 of the second protrusion stack structure PST2.

The second part 122b2 may be provided between the first parts 122b1. The first part 122b1 and the second part 122b2 may be alternately disposed along the second direction D2. The first protrusion stack structure PST1 and the second protrusion stack structure PST2 may be disposed between the first parts 122b1.

The width of the second part 122b2 in the first direction D1 may be defined as a fifth width W5. The width of the first part 122b1 in the first direction D1 may be defined as a sixth width W6. The fifth width W5 may be smaller than the sixth width W6. The fifth width W5 may be equal to the fifth distance L5 (see FIG. 1B). The sixth width W6 may be equal to the sixth distance L6 (see FIG. 1B).

The width of the second part 122b2 in the second direction D2 may be defined as a seventh width W7. The seventh width W7 may be equal to the first width W1 (see FIG. 1B) or the third width W3 (see FIG. 1B). The width of the second part 122b2 in the second direction D2 may be equal to the width of the first protrusion stack structure PST1 in the second direction D2 or that of the second protrusion stack structure PST2 in the second direction D2.

The deepest depth of the second insulating part 122 may be defined as a second depth DP2. The second depth DP2 of the second insulating part 122 may be greater than the first depth DP1 of the first insulating part 121.

In the semiconductor device, in accordance with this embodiment, because the second depth DP2 of the second insulating part 122 is greater than the first depth DP1 of the first insulating part 121, it may be relatively highly likely that a void will be formed in the second insulating part 122.

In the semiconductor device, the width of the second part 122b2 of the second insulating part 122 can be formed to be relatively narrowed by forming the first protrusion stack structure PST1 and the second protrusion stack structure PST2. Accordingly, any void can be suppressed from being formed in the second part 122b2 of the upper portion 122b of the second insulating part 122, any void can be suppressed from being formed in the first part 122b1 of the upper portion 122b of the second insulating part 122, and any void can be suppressed from being formed in the lower portion 122a of the second insulating part 122.

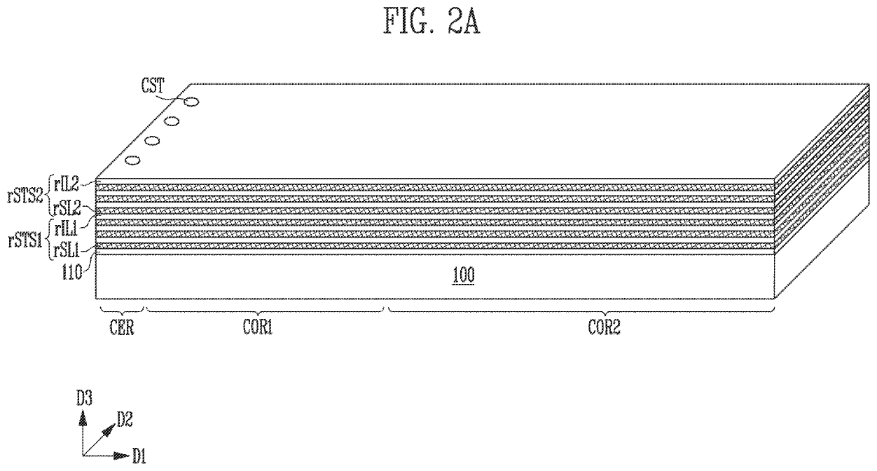

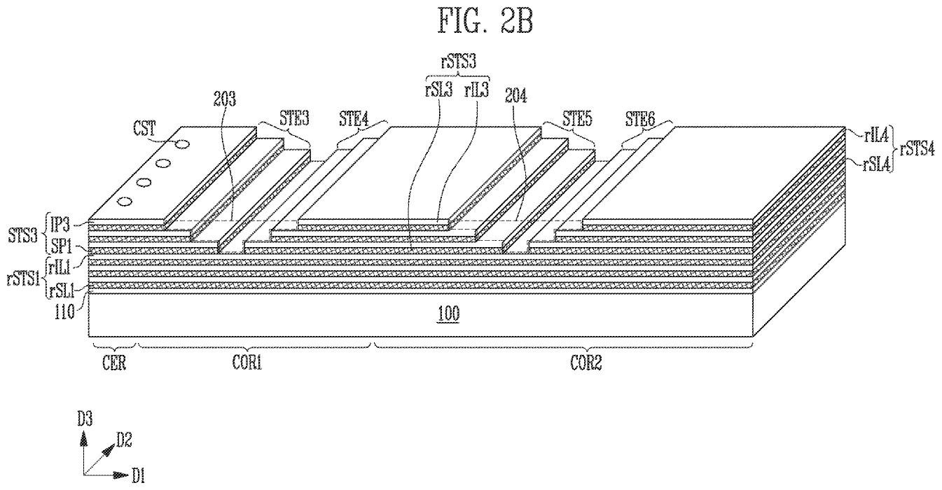

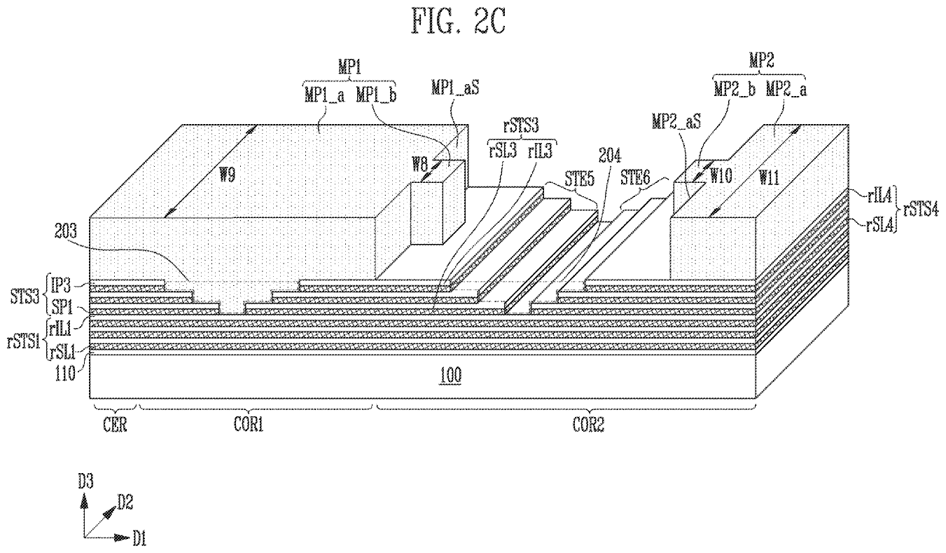

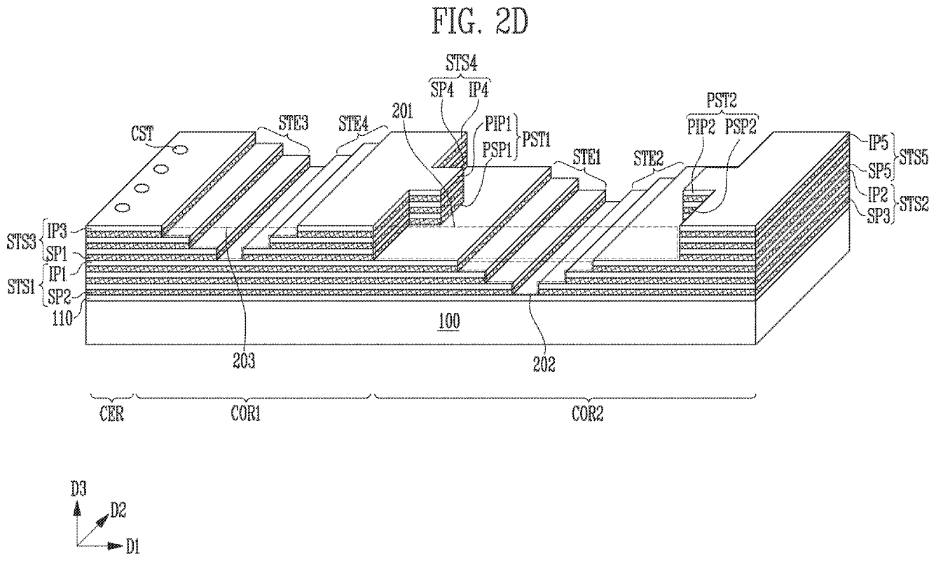

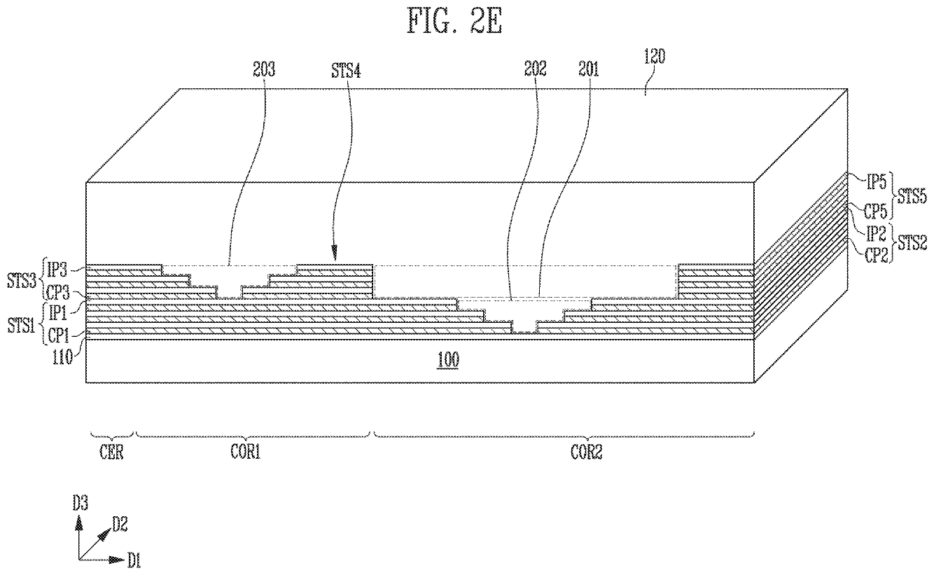

FIGS. 2A, 2B, 2C, 2D, and 2E are perspective views, illustrating a manufacturing method of the semiconductor device, shown in FIGS. 1A, 1B, 1C, and 1D. For convenience of description, components identical to those described with reference to FIGS. 1A, 1B, 1C, and 1D are designated by like reference numerals, and their overlapping descriptions will be omitted. A manufacturing method described below is merely one embodiment of the manufacturing method of the semiconductor memory device shown in FIGS. 1A, 1B, 1C, and 1D, and the manufacturing method of the semiconductor memory device shown in FIGS. 1A, 1B, 1C, and 1D might not be limited to that described below.

Referring to FIG. 2A, a first insulating layer 110 may be formed on a base part 100. The base part 100 may include a source structure. The first insulating layer 110 may include an insulating material.

A first preliminary stack structure rSTS1 may be formed on the first insulating layer 110. The first preliminary stack structure rSTS1 may include first preliminary insulating layers rIL1 and first preliminary sacrificial layers rSL1, alternately stacked in a third direction D3. The first preliminary insulating layers rIL1 may include an insulating material. In an example, the first preliminary insulating layers rIL1 may include oxide. The first preliminary sacrificial layers rSL1 may include a material different from that of the first preliminary insulating layers rIL1. In an example, the first preliminary sacrificial layers rSL1 may include nitride.

A second preliminary stack structure rSTS2 may be formed on the first preliminary stack structure rSTS1. The second preliminary stack structure rSTS2 may include second preliminary insulating layers rIL2 and second preliminary sacrificial layers rSL2, alternately stacked in the third direction D3. The second preliminary insulating layers rIL2 may include an insulating material. The second preliminary sacrificial layers rSL2 may include a material different from that of the second preliminary insulating layers rIL2.

Cell plugs CST, penetrating the first preliminary stack structure rSTS1, the second preliminary stack structure rSTS2, and the first insulating layer 110, may be formed in a cell region CER. The cell plug CST may include a channel layer and a memory layer. The forming of the cell plug CST may include forming a hole penetrating the first preliminary stack structure rSTS1, the second preliminary stack structure rSTS2, and the first insulating layer 110 and forming the memory layer and the channel layer in the hole.

Referring to FIG. 2B, the second preliminary stack structure rSTS2 may be etched. When the second preliminary stack structure rSTS2 is etched, a third stack structure STS3, a third preliminary stack structure rSTS3, and a fourth preliminary stack structure rSTS4 may be formed on the first preliminary stack structure rSTS1.

The third stack structure STS3, the third preliminary stack structure rSTS3, and the fourth preliminary stack structure rSTS4 may be sequentially arranged in a first direction D1. The third stack structure STS3, the third preliminary stack structure rSTS3, and the fourth preliminary stack structure rSTS4 may be spaced apart from each other in the first direction D1.

The third stack structure STS3 may include third insulating patterns IP3 and first sacrificial patterns SP1. The third insulating patterns IP3 of the third stack structure STS3 may be formed by etching the second preliminary insulating layers rIL2 of the second preliminary stack structure rSTS2. The first sacrificial patterns SP1 of the third stack structure STS3 may be formed by etching the second preliminary sacrificial layers rSL2 of the second preliminary stack structure rSTS2.

The third preliminary stack structure rSTS3 may include third preliminary insulating layers rIL3 and third preliminary sacrificial layers rSL3. The third preliminary insulating layers rIL3 of the third preliminary stack structure rSTS3 may be formed by etching the second preliminary insulating layers rIL2 of the second preliminary stack structure rSTS2. The third preliminary sacrificial layers rSL3 of the third preliminary stack structure rSTS3 may be formed by etching the second preliminary sacrificial layers rSL2 of the second preliminary stack structure rSTS2.

The fourth preliminary stack structure rSTS4 may include fourth preliminary insulating layers rIL4 and fourth preliminary sacrificial layers rSL4. The fourth preliminary insulating layers rIL4 of the fourth preliminary stack structure rSTS4 may be formed by etching the second preliminary insulating layers rIL2 of the second preliminary stack structure rSTS2. The fourth preliminary sacrificial layers rSL4 of the fourth preliminary stack structure rSTS4 may be formed by etching the second preliminary sacrificial layers rSL2 of the second preliminary stack structure rSTS2.

The third stack structure STS3 may be disposed in the cell region CER and a first connection region COR1. The third stack structure STS3 may include a third stepped structure STE3. The third stepped structure STE3 of the third stack structure STS3 may be defined by the third insulating patterns IP3 and the first sacrificial patterns SP1 of the third stack structure STS3. The third stepped structure STE3 may be disposed in the first connection region COR1.

The third preliminary stack structure rSTS3 may be disposed in the first connection region COR1 and a second connection region COR2. The third preliminary stack structure rSTS3 may include a fourth stepped structure STE4 and a fifth stepped structure STE5. The fourth stepped structure STE4 and the fifth stepped structure STE5 of the third preliminary stack structure rSTS3 may be defined by the third preliminary insulating layers rIL3 and the third preliminary sacrificial layers rSL3 of the third preliminary stack structure rSTS3. The fourth stepped structure STE4 may be disposed in the first connection region COR1. The fourth stepped structure STE4 and the third stepped structure STE3 may have a structure in which the fourth stepped structure STE4 and the third stepped structure STE3 are symmetrical with respect to a space between the fourth stepped structure STE4 and the third stepped structure STE3. The fifth stepped structure STE5 may be disposed in the second connection region COR2. The fifth stepped structure STE5 and fourth stepped structure STE4 may have a structure in which the fifth stepped structure STE5 and fourth stepped structure STE4 are symmetrical with respect to a space between the fifth stepped structure STE5 and fourth stepped structure STE4.

The fourth preliminary stack structure rSTS4 may be disposed in the second connection region COR2. The fourth preliminary stack structure rSTS4 may include a sixth stepped structure STE6. The sixth stepped structure STE6 of the fourth preliminary stack structure rSTS4 may be defined by the fourth preliminary insulating layers rIL4 and the fourth preliminary sacrificial layers rSL4 of the fourth preliminary stack structure rSTS4. The sixth stepped structure STE6 may be disposed in the second connection region COR2. The sixth stepped structure STE6 and the fifth stepped structure STE5 may have a structure in which the sixth stepped structure STE6 and the fifth stepped structure STE5 are symmetrical with respect to a space between the sixth stepped structure STE6 and the fifth stepped structure STE5.

The third to sixth stepped structures STE3, STE4, STE5, and STE6 may be disposed at the same level. The third to sixth stepped structures STE3, STE4, STE5, and STE6 may be formed by etching the second preliminary insulating layers rIL2 and the second preliminary sacrificial layers rSL2 of the second preliminary stack structure rSTS2.

A third space 203 may be formed between the third and fourth stepped structures STE3 and STE4 by etching the second preliminary stack structure rSTS2. A fourth space 204 may be formed between the fifth and sixth stepped structures STE5 and STE6 by etching the second preliminary stack structure rSTS2.

Referring to FIG. 2C, a first mask pattern MP1 may be formed on the third stack structure STS3 and the third preliminary stack structure rSTS3, and a second mask pattern MP2 may be formed on the fourth preliminary stack structure rSTS4.

The first mask pattern MP1 may include a first part MP1_a and a second part MP1_b. The first part MP1_a may be provided in the cell region CER and the first connection region COR1. The second part MP1_b may be provided in the second connection region COR2. The shortest distance between the second part MP1_b and the fifth stepped structure STE5 may be smaller than that between the first part MP1_a and the fifth stepped structure STE5.

The first part MP1_a may fill a space between the third and fourth stepped structures STE3 and STE4. The first part MP1_a may fill the third space 203. The second part MP1_b may protrude toward the fifth stepped structure STE5 from a sidewall MP1_aS of the first part MP1_a. The second part MP1_b may protrude in the first direction D1 from the sidewall MP1_aS of the first part MP1_a. The sidewall MP1_aS of the first part MP1_a may be a sidewall that is adjacent to the fifth stepped structure STE5.

The width of the second part MP1_b may be smaller than the width of the first part MP1_a. The width of the second part MP1_b in a second direction D2 may be defined as an eighth width W8. The width of the first part MP1_a in the second direction D2 may be defined as a ninth width W9. The eighth width W8 may be smaller than the ninth width W9.

The fifth stepped structure STE5 may be exposed by the first mask pattern MP1. In another words, the first mask pattern MP1 might not cover the fifth stepped structure STE5 of the third preliminary stack structure rSTS3. A portion of a top surface of the third preliminary stack structure rSTS3 may be exposed by the first mask pattern MP1. In other words, the first mask pattern MP1 may cover only a portion of the top surface of the third preliminary stack structure rSTS3.

The second mask pattern MP2 may include a first part MP2_a and a second part MP2_b. The second mask pattern MP2 may be provided in the second connection region COR2. The shortest distance between the second part MP2_b and the sixth stepped structure STE6 may be smaller than that between the first part MP2_a and the sixth stepped structure STE6.

The second part MP2_b may protrude toward the sixth stepped structure STE6 from a sidewall MP2_aS of the first part MP2_a. The second part MP2_b may protrude in the opposite direction of the first direction from the sidewall MP2_aS of the first part MP2_a. The sidewall MP2_aS of the first part MP2_a may be a sidewall that is adjacent to the sixth stepped structure STE6.

The width of the second part MP2_b may be smaller than the width of the first part MP2_a. The width of the second part MP2_b in the second direction D2 may be defined as a tenth width W10. The width of the first part MP2_a in the second direction D2 may be defined as an eleventh width W11. The tenth width W10 may be smaller than the eleventh width W11.

The sixth stepped structure STE6 may be exposed by the second mask pattern MP2. In other words, the second mask pattern MP2 might not cover the sixth stepped structure STE6 of the fourth preliminary stack structure rSTS4. A portion of a top surface of the fourth preliminary stack structure rSTS4 may be exposed by the second mask pattern MP2. In other words, the second mask pattern MP2 may cover only a portion of the top surface of the fourth preliminary stack structure rSTS4.

The first and second mask patterns MP1 and MP2 may expose the fourth space 204. The fifth and sixth stepped structures STE5 and STE6, the portion of the top surface of the third preliminary stack structure rSTS3, and the portion of the top surface of the fourth preliminary stack structure rSTS4 may be exposed by the first and second mask patterns MP1 and MP2. The fifth and sixth stepped structures STE5 and STE6, the portion of the top surface of the third preliminary stack structure rSTS3, and the portion of the top surface of the fourth preliminary stack structure rSTS4 may be exposed between the first and second mask patterns MP1 and MP2.

Referring to FIG. 2D, the first preliminary stack structure rSTS1, the third preliminary stack structure rSTS3, and the fourth preliminary stack structure rSTS4 may be etched by using the first mask pattern MP1 and the second mask pattern MP2 as an etching barrier.

A first stack structure STS1 and a second stack structure STS2 may be formed by etching the first preliminary stack structure rSTS1. The first and second stack structures STS1 and STS2 may be spaced apart from each other in the first direction D1.

The first stack structure STS1 may include first insulating patterns IP1 and second sacrificial patterns SP2. The first insulating patterns IP1 of the first stack structure STS1 may be formed by etching the first preliminary insulating layers rIL1 of the first preliminary stack structure rSTS1. The second sacrificial patterns SP2 of the first stack structure STS1 may be formed by etching the first preliminary sacrificial layers rSL1 of the first preliminary stack structure rSTS1.

The second stack structure STS2 may include second insulating patterns IP2 and third sacrificial patterns SP3. The second insulating patterns IP2 of the second stack structure STS2 may be formed by etching the first preliminary insulating layers rIL1 of the first preliminary stack structure rSTS1. The third sacrificial patterns SP3 of the second stack structure STS2 may be formed by etching the first preliminary sacrificial layers rSL1 of the first preliminary stack structure rSTS1.

The first stack structure STS1 may be in the cell region CER, the first connection region COR1, and the second connection region COR2. The first stack structure STS1 may include a first stepped structure STE1. The first stepped structure STE1 may be defined by the first insulating patterns IP1 and the second sacrificial patterns SP2 of the first stack structure STE1. The first stepped structure STE1 may be disposed in the second connection region COR2.

The second stack structure STS2 may be disposed in the second connection region COR2. The second stacked structure STS2 may include a second stepped structure STE2. The second stepped structure STE2 may be defined by the second insulating patterns IP2 and the third sacrificial patterns SP3 of the second stacked structure STE2. The first stepped structure STE1 and the second stepped structure STE2 may have a structure in which the second stepped structure STE2 and the first stepped structure STE1 are symmetrical with respect to the space between the first and second stepped structures STE1 and STE2.

The first and second stepped structures STE1 and STE2 may be disposed at the same level. The first and second stepped structures STE1 and STE2 may be formed by etching the first preliminary insulating layers rIL1 and the first preliminary sacrificial layer rSL1 of the first preliminary stack structure rSTS1. The first stepped structure STE1 may be formed by etching the fifth stepped structure STE5 uniformly. The first stepped structure STE1 may be formed by transferring the fifth stepped structure STE5 downwardly. The second stepped structure STE2 may be formed by etching the sixth stepped structure uniformly. The second stepped structure STE2 may be formed by transferring the sixth stepped structure downwardly. A second space 202 between the first and second stepped structures STE1 and STE2 may be formed by etching the fourth space 204 (see FIG. 2C) uniformly. The second space 202 between the first and second stepped structures STE1 and STE2 may be formed by transferring the fourth space 204 (see FIG. 2C) downwardly.

A fourth stack structure STS4 and a first protrusion stack structure PST1 may be formed by etching the third preliminary stack structure rSTS3.

The fourth stack structure STS4 may include fourth insulating patterns IP4 and fourth sacrificial patterns SP4. The fourth insulating patterns IP4 of the fourth stack structure STS4 may be formed by etching the third preliminary insulating layers rIL3 of the third preliminary stack structure rSTS3. The fourth sacrificial patterns SP4 of the fourth structure STS4 may be formed by etching the third preliminary sacrificial layers rSL3 of the third preliminary stack structure rSTS3.

The first protrusion stack structure PST1 may include first protrusion insulating patterns PIP1 and first protrusion sacrificial patterns PSP1. The first protrusion insulating patterns PIP1 of the first protrusion stack structure PST1 may be formed by etching the third preliminary insulating layers rIL3 of the third preliminary stack structure rSTS3. The first protrusion sacrificial patterns PSP1 of the first protrusion stack structure PST1 may be formed by etching the third preliminary sacrificial layers rSL3 of the third preliminary stack structure rSTS3. The first protrusion stack structure PST1 may overlap with the second part MP1_b of the first mask pattern MP1. The first protrusion stack structure PST1 may be formed based on the shape of the second part MP1_b of the first mask pattern MP1.

The fourth stack structure STS4 and the first protrusion stack structure PST1 may be continuously formed without any boundary. The fourth insulating patterns IP4 of the fourth stack structure STS4 and the first protrusion insulating patterns PIP1 of the first protrusion stack structure PST1 may be continuously formed without any boundary. The fourth sacrificial patterns SP4 of the fourth stack structure STS4 and the first protrusion sacrificial patterns PSP1 of the first protrusion stack structure PST1 may be continuously formed without any boundary.

A fifth stack structure STS5 and a second protrusion stack structure PST2 may be formed by etching the fourth preliminary stack structure rSTS4.

The fifth stack structure STS5 may include fifth insulating patterns IP5 and fifth sacrificial patterns SP5. The fifth insulating patterns IP5 of the fifth stack structure STS5 may be formed by etching the fourth preliminary insulating layers rIL4 of the fourth preliminary stack structure rSTS4. The fifth sacrificial patterns SP5 of the fifth stack structure STS5 may be formed by etching the fourth preliminary sacrificial layer rSL4 of the fourth preliminary stack structure rSTS4.

The second protrusion stack structure PST2 may include second protrusion insulating patterns PIP2 and second protrusion sacrificial patterns PSP2. The second protrusion insulating patterns PIP2 of the second protrusion stack structure PST2 may be formed by etching the fourth preliminary insulating layers rIL4 of the fourth preliminary stack structure rSTS4. The second protrusion sacrificial patterns PSP2 of the second protrusion stack structure PST2 may be formed by etching the fourth preliminary sacrificial layers rSL4 of the fourth preliminary stack structure rSTS4. The second protrusion stack structure PST2 may be a portion that overlaps with the second part MP2_b of the second mask pattern MP2. The second protrusion stack structure PST2 may be formed based on the shape of the second part MP2_b of the second mask pattern MP2.

The fifth stack structure STS5 and the second protrusion stack structure PST2 may be continuously formed without any boundary. The fifth insulating patterns IP5 of the fifth stack structure STS5 and the second protrusion insulating patterns PIP2 of the second protrusion stack structure PST2 may be continuously formed without any boundary. The fifth sacrificial patterns SP5 of the fifth stack structure STS5 and the second protrusion sacrificial patterns PSP2 of the second protrusion stack structure PST2 may be continuously formed without any boundary.

A first space 201 may be formed between the fourth and fifth stack structures STS4 and STS5 by etching the third and fourth preliminary stack structures rSTS3 and rSTS4. The first space 201 may be connected to the second space 202.

Referring to FIG. 2E, a second insulating layer 120 may be formed, which covers the first to fifth stack structures STS1, STS2, STS3, STS4, and STS5 and the first and second protrusion stack structures PST1 and PST2. The second insulating layer 120 may fill the first to third spaces 201, 202, and 203. The first insulating part 121 (see FIG. 1E) of the second insulating layer 120 may fill the third space 203. The second insulating part 122 (see FIG. 1F) of the second insulating layer 120 may fill the first and second spaces 201 and 202.

Subsequently, the first to fifth sacrificial patterns SP1, SP2, SP3, SP4, and SP5 and the first and second protrusion sacrificial patterns PSP1 and PSP2 may be removed, and first to fifth conductive patterns CP1, CP2, CP3, CP4, and CP5 and first to second protrusion patterns PCP1 and PCP2 may be formed. Subsequently, the word line contacts WCT (see FIGS. 1C and 1D) that penetrate the second insulating layer 120 may be formed.

In the manufacturing method of the semiconductor device, in accordance with this embodiment, the first and second protrusion stack structures PST1 and PST2 are formed based on the shapes of the second part MP1_b of the first mask pattern MP1 and the second part MP2_b of the second mask pattern MP2, so that the first space 201 between the fourth and fifth stack structures STS4 and STS5 can be formed to be partially narrow. Accordingly, when the first space 201 between the fourth and fifth stack structures STS4 and STS5 and the second space 202 between the first and second stepped structures STE1 and STE2 are filled with the second insulating layer 120, any void can be suppressed from being formed in the second insulating layer 120, and the structural stability of the semiconductor device can be improved.

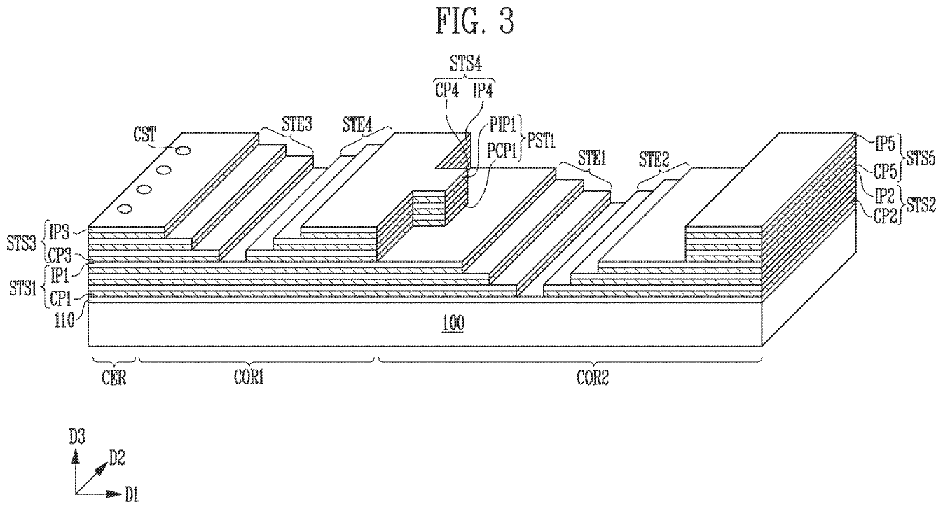

FIG. 3 is a perspective view of a semiconductor device in accordance with an embodiment of the present disclosure.

The semiconductor device may be similar to the semiconductor device in accordance with the embodiment, shown in FIGS. 1A, 1B, 1C, and 1D, except portions described below.

Referring to FIG. 3, a first stepped structure STE1 of a first stack structure STS1 and a second stepped structure STE2 of a second stack structure STS2 may be provided, which are symmetrically with each other.

A fourth stack structure STS4 and a first protrusion stack structure PST1 may be provided on the first stack structure STS1. The first protrusion stack structure PST1 may protrude laterally toward the first stepped structure STE1 from a sidewall of the fourth stack structure STS4. The sidewall of the fourth stack structure STS4 may be a sidewall that is adjacent to the first stepped structure STE1.

A fifth stack structure STS5 may be provided on the second stack structure STS2. A protrusion stack structure might not be formed on the second stack structure STS2. In other words, a protrusion stack structure might not be formed, which protrudes toward the second stepped structure STE2 from a sidewall of the fifth stack structure STS5. The sidewall of the fifth stack structure STS5 may be a sidewall that is adjacent to the second stepped structure STE2.

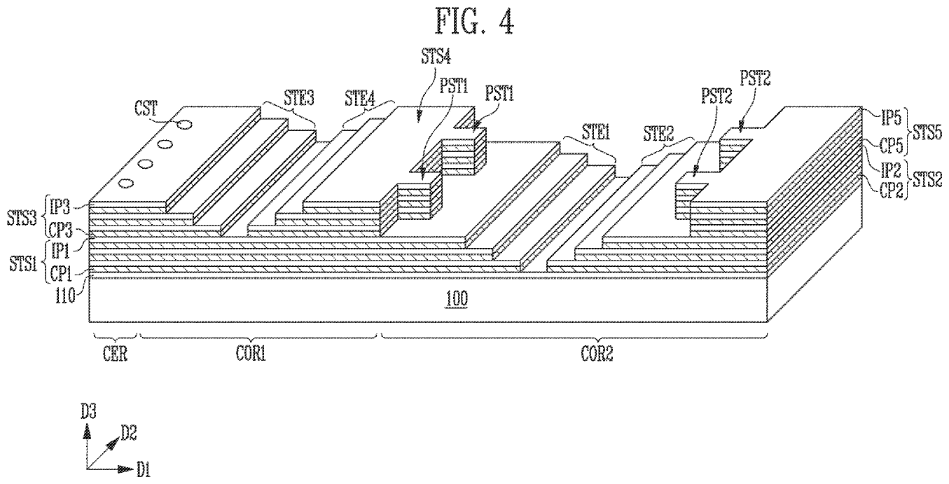

FIG. 4 is a perspective view of a semiconductor device in accordance with an embodiment of the present disclosure.

The semiconductor device may be similar to the semiconductor device in accordance with the embodiment, shown in FIGS. 1A, 1B, 1C, and 1D, except portions described below.

Referring to FIG. 4, a first stepped structure STE1 of a first stack structure STS1 and a second stepped structure STE2 of a second stack structure STS2 may be provided, which are symmetrically with each other.

A fourth stack structure STS4 and a plurality of first protrusion stack structures PST1 may be provided on the first stack structure STS1. The plurality of first protrusion stack structures PST1 may protrude toward the first stepped structure STE1 from a sidewall of the fourth stack structure STS4. The sidewall of the fourth stack structure STS4 may be a sidewall that is adjacent to the first stepped structure STE1.

A fifth stack structure STS5 and a plurality of second protrusion stack structures PST2 may be provided on the second stack structure STS2. The plurality of second protrusion stack structures PST2 may protrude toward the second stepped structure STE2 from a sidewall of the fifth stack structure STS5. The sidewall of the fifth stack structure STS5 may be a sidewall that is adjacent to the second stepped structure STE2.

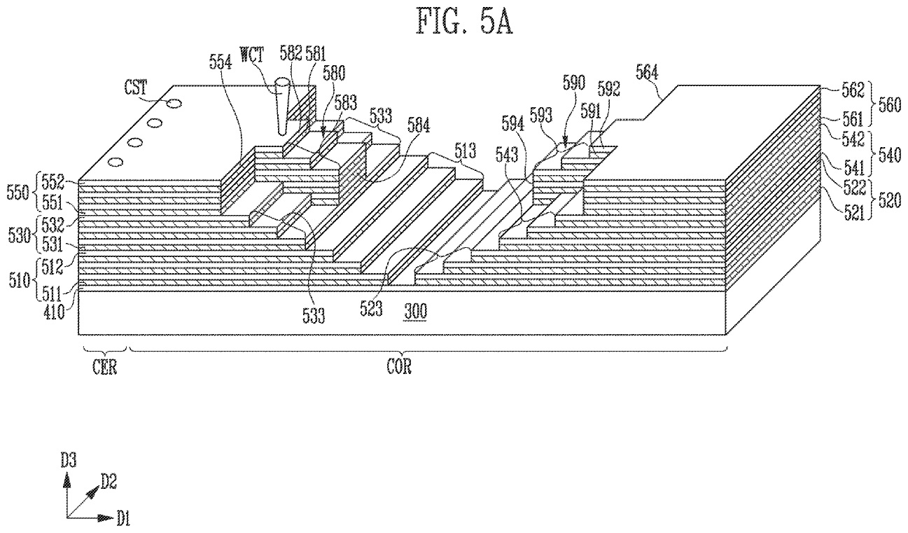

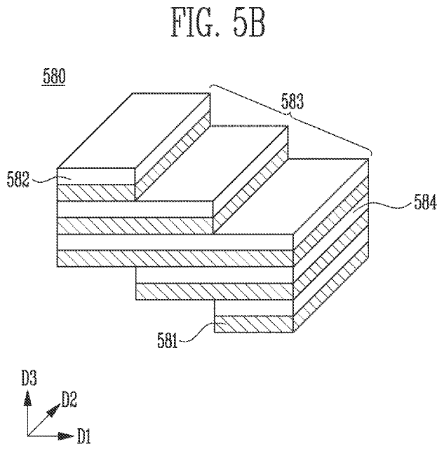

FIG. 5A is a perspective view of a semiconductor device in accordance with an embodiment of the present disclosure. FIG. 5B is a perspective view illustrating an isolation stack structure shown in FIG. 5A.

Referring to FIGS. 5A and 5B, the semiconductor device in accordance with this embodiment may include a base part 300. In an example, the base part 300 may include a source structure.

A first insulating layer 410 may be provided on the base part 300. The first insulating layer 410 may include an insulating material. In an example, the first insulating layer 410 may include oxide.

The semiconductor device in accordance with this embodiment may include a cell region CER and a connection region COR. Cell structures CST may be disposed in the cell region CER. Word line contacts WCT may be disposed in the connection region COR.

A first stack structure 510 may be provided on the first insulating layer 410. The first stack structure 510 may include first conductive patterns 511 and first insulating patterns 512, alternately stacked in a third direction D3. The first conductive pattern 511 and the first insulating pattern 512, which are adjacent to each other, may be defined as one stacked pair. Although a case where the first stack structure 510 includes three stacked pairs is illustrated, the present disclosure is not limited thereto. The first stack structure 510 may extend up to the connection region COR from the cell region CER.

The first stack structure 510 may include a first stepped structure 513. The first stepped structure 513 may be defined by the first insulating patterns 512 and the first conductive patterns 511. The first stepped structure 513 may be disposed in the connection region COR.

A second stack structure 520 may be provided on the first insulating layer 410. The second stack structure 520 may include second conductive patterns 521 and second insulating patterns 522, alternately stacked in the third direction D3. Although a case where the second stack structure 520 includes three stacked pairs is illustrated, the present disclosure is not limited thereto.

The second stack structure 520 may be disposed in the connection region COR. The second stack structure 520 may be spaced apart from the first stack structure 510 in a first direction D1. The second stack structure 520 may be disposed at the same level as the first stack structure 510.

The second stack structure 520 may include a second stepped structure 523. The second stepped structure 523 may be defined by the second insulating patterns 522 and the second conductive patterns 521. The second stepped structure 523 may be disposed in the connection region COR.

The second stepped structure 523 may face the first stepped structure 513. The second stepped structure 523 and the first stepped structure 513 may have a structure in which the second stepped structure 523 and the first stepped structure 513 are symmetrical with respect to a space between the first and second stepped structures 513 and 523. The second stepped structure 523 may be disposed at the same level as the first stepped structure 513.

A third stack structure 530 may be provided on the first stack structure 510. The third stack structure 530 may include third conductive patterns 531 and third insulating patterns 532, alternately stacked in the third direction D3. Although a case where the third stack structure 530 includes three stacked pairs is illustrated, the present disclosure is not limited thereto. The third stack structure 530 may extend up to the connection region COR from the cell region CER.

The third stack structure 530 may include third stepped structures 533. The third stepped structures 533 may be defined by the third insulating patterns 532 and the third conductive patterns 531. The third stepped structures 533 may be disposed at a higher level than the level of the first and second stepped structures 513 and 523. The third stepped structure 533 may be disposed farther away from the second stepped structure 523 than the first stepped structure 513. The distance between the third stepped structure 533 and the second stepped structure 523 in the first direction D1 may be greater than that between the first stepped structure 513 and the second stepped structure 523 in the first direction D1.

A fourth stack structure 540 may be provided on the second stack structure 520. The fourth stack structure 540 may include fourth conductive patterns 541 and fourth insulating patterns 542, alternately stacked in the third direction D3. Although a case where the fourth stack structure 540 includes three stacked pairs is illustrated, the present disclosure is not limited thereto. The fourth stack structure 540 may be disposed in the connection region COR. The fourth stack structure 540 may be spaced apart from the third stack structure 530 in the first direction D1.

The fourth stack structure 540 may include fourth stepped structures 543. The fourth stepped structures 543 may be defined by the fourth insulating patterns 542 and the fourth conductive patterns 541. The fourth stepped structure 543 may face the third stepped structure 533. The fourth stepped structure 543 and the third stepped structure 533 may have a structure in which the fourth stepped structure 543 and the third stepped structure 533 are symmetrical with respect to a space between the third and fourth stepped structures 533 and 543. The fourth stepped structure 543 may be disposed at the same level as the third stepped structure 533. The fourth stepped structures 543 may be disposed at a higher level than the level of the first and second stepped structures 513 and 523. The fourth stepped structure 543 may be disposed farther away from the first stepped structure 513 than the second stepped structure 523. The distance between the fourth stepped structure 543 and the first stepped structure 513 in the first direction D1 may be greater than that between the second stepped structure 523 and the first stepped structure 513 in the first direction D1.

A fifth stack structure 550 may be provided on the third stack structure 530. The fifth stack structure 550 may include fifth conductive patterns 551 and fifth insulating patterns 552, alternately stacked in the third direction D3. Although a case where the fifth stack structure 550 includes three staked pairs is illustrated, the present disclosure is not limited thereto. The fifth stack structure 550 may extend up to the connection region COR from the cell region CER.

The fifth stack structure 550 may include a first sidewall 554. The first sidewall 554 may be defined by sidewalls of the fifth insulating patterns 552 and sidewalls of the fifth conductive patterns 551, which form a common surface. The first sidewall 554 may be disposed in the connection region COR.

The first sidewall 554 may be disposed at a higher level than the level of the third and fourth stepped structures 533 and 543. The first sidewall 554 may be disposed more distance from the fourth stepped structure 543 than the third stepped structure 533. The distance between the first sidewall 554 and the fourth stepped structure 543 in the first direction D1 may be greater than that between the third stepped structure 533 and the fourth stepped structure 543 in the first direction D1.

A sixth stack structure 560 may be provided on the fourth stack structure 540. The sixth stack structure 560 may include sixth conductive patterns 561 and sixth insulating patterns 562, alternately stacked in the third direction D3. Although a case where the sixth stack structure 560 includes three stacked pairs is illustrated, the present disclosure is not limited thereto.

The sixth stack structure 560 may be disposed in the connection region COR. The sixth stack structure 560 may be disposed at the same level as the fifth stack structure 550. The sixth stack structure 560 may be spaced apart from the fifth stack structure 550 in the first direction D1.

The sixth stack structure 560 may include a second sidewall 564. The second sidewall 564 may be defined by sidewalls of the sixth insulating patterns 562 and sidewalls of the sixth conductive patterns 561, which form a common surface. The second sidewall 564 may be disposed in the connection region COR.

The second sidewall 564 may face the first sidewall 554. The second sidewall 564 may be disposed at the same level as the first sidewall 554. The second sidewall 564 may be disposed at a higher level than the level of the third and fourth stepped structures 533 and 543. The second sidewall 564 may be disposed farther away from the third stepped structure 533 than the fourth stepped structure 543. The distance between the second sidewall 564 and the third stepped structure 533 in the first direction D1 may be greater than that between the fourth stepped structure 543 and the third stepped structure 533 in the first direction D1.

A first isolation stack structure 580 may be provided on the third stack structure 530. The first isolation stack structure 580 may include first isolation conductive patterns 581 and first isolation insulating patterns 582, alternately stacked in the third direction D3. Although a case where the first isolation stack structure 580 includes six stacked pairs is illustrated, the present disclosure is not limited thereto. A number of the stacked pairs included in the first isolation stack structure 580 may be equal to the sum of numbers of the stacked pairs included in the third and fifth stacked structures 530 and 550.

The first isolation stack structure 580 may be disposed in the connection region COR. The first isolation stack structure 580 may be disposed between the third stepped structures 533. The third stepped structures 533 may be spaced apart from each other in a second direction D2 by the first isolation stack structure 580. The first isolation stack structure 580 may protrude in the third direction D3 from surfaces of the third stepped structures 533. The first isolation stack structure 580 may protrude in the first direction D1 from the first sidewall 554. The first isolation stack structure 580 may be disposed at a higher level than the level of the third stepped structure 533.

The first isolation stack structure 580 and the third and fifth stack structures 530 and 550 may be continuously formed without any boundary. The first isolation conductive patterns 581 of the first isolation stack structure 580 may be continuously formed without any boundary with the third conductive patterns 531 of the third stack structure 530 or the fifth conductive patterns 551 of the fifth stack structure 550. The first isolation insulating patterns 582 of the first isolation stack structure 580 may be formed with the third insulating patterns 532 of the third stack structure 530 or the fifth insulating patterns 552 of the fifth stack structure 550 without any boundary.

The first isolation stack structure 580 may include a fifth stepped structure 583. The fifth stepped structure 583 may be defined by the first isolation insulating patterns 582 and the first isolation conductive patterns 581. The fifth stepped structure 583 may be disposed in the connection region COR. The fifth stepped structure 583 may be disposed at the same level as the first and second sidewalls 554 and 564. The fifth stepped structure 583 may be disposed at a higher level than the level of the third and fourth stepped structures 533 and 543. A top surface of the first isolation stack structure 580 may be formed in a stepped structure, to define the fifth stepped structure 583.

The first isolation stack structure 580 may include a third sidewall 584. The third sidewall 584 may be defined by sidewalls of the first isolation conductive patterns 581 and sidewalls of the first isolation insulating patterns 582, which form a common surface. The third sidewall 584 may be disposed in the connection region CER. The third sidewall 584 may be disposed at a level lower than that of the fifth stepped structure 583. The third sidewall 584 may be disposed at the same level as the third and fourth stepped structures 533 and 543. The height of the third sidewall 584 may be equal to the height of the third stack structure 530.

A second isolation stack structure 590 may be provided on the fourth stack structure 540. The second isolation stack structure 590 may include second isolation conductive patterns 591 and second isolation insulating patterns 592, alternately stacked in the third direction D3. Although a case where the second isolation stack structure 590 includes six stacked pairs is illustrated, the present disclosure is not limited thereto. A number of the stacked pairs included in the second isolation stack structure 590 may be equal to the sum of numbers of the stacked pairs included in the fourth and sixth stack structures 540 and 560.

The second isolation stack structure 590 may be disposed in the connection region COR. The second isolation stack structure 590 may be disposed between the fourth stepped structures 543. The fourth stepped structures 534 may be spaced apart from each other in the second direction D2 by the second isolation stack structure 590. The second isolation stack structure 590 may protrude in the third direction D3 from surfaces of the fourth stepped structures 543. The second isolation stack structure 590 may protrude in the opposite direction of the first direction D1 from the second sidewall 574. The second isolation stack structure 590 may be disposed at a higher level than the level of the fourth stepped structure 543. The second isolation stack structure 590 may face the first isolation stack structure 580. The second isolation stack structure 590 and the first isolation stack structure 580 may have a structure in which the second isolation stack structure 590 and the first isolation stack structure 580 are symmetrical with respect to a space between the first and second isolation stack structures 580 and 590.

The second isolation stack structure 590 and the fourth and sixth stack structures 540 and 560 may be continuously formed without any boundary. The second isolation conductive patterns 591 of the second isolation stack structure 590 may be continuously formed without any boundary with the fourth conductive patterns 541 of the fourth stack structure 540 or the sixth conductive patterns 561 of the sixth stack structure 560. The second isolation insulating patterns 592 of the second isolation stack structure 590 may be continuously formed without any boundary with the fourth insulating patterns 542 of the fourth stack structure 540 or the sixth insulating patterns 562 of the sixth stack structure 560.

The second isolation stack structure 590 may include a sixth stepped structure 593. The sixth stepped structure 593 may be defined by the second isolation insulating patterns 592 and the second isolation conductive patterns 591. The sixth stepped structure 593 may be disposed in the connection region COR. The sixth stepped structure 593 may face the fifth stepped structure 583. The sixth stepped structure 593 and the fifth stepped structure 583 may have a structure in which the sixth stepped structure 593 and the fifth stepped structure 583 are symmetrical with respect to a space between the fifth and sixth stepped structures 583 and 593. The sixth stepped structure 593 may be disposed at the same level as the first and second sidewalls 554 and 564 and the fifth stepped structure 583. The sixth stepped structure 593 may be disposed at a higher level than the level of the third and fourth stepped structures 533 and 543. A top surface of the second isolation stack structure 590 may be formed in a stepped shape, to define the sixth stepped structure 593.

The second isolation stack structure 590 may include a fourth sidewall 594. The fourth sidewall 594 may be defined by sidewalls of the second isolation conductive patterns 591 and sidewalls of the second isolation insulating patterns 592, which form a common surface. The fourth sidewall 594 may be disposed in the connection region COR. The fourth sidewall 594 may face the third sidewall 584. The fourth sidewall 594 may be disposed at a level lower than that of the fifth and sixth stepped structures 583 and 593. The fourth sidewall 594 may be disposed at the same level as the third and fourth stepped structures 533 and 543. The height of the fourth sidewall 594 may be equal to the height of the fourth stack structure 540.

A second insulating layer may be provided, which covers the first to sixth stack structures 510, 520, 530, 540, 550, and 560 and the first and second isolation stack structures 580 and 590. The second insulating layer may fill a space between the first and second stack structures 510 and 520, a space between the third and fourth stack structures 530 and 540, and a space between the fifth and sixth stack structures 550 and 560. The word line contacts WCT may penetrate the second insulating layer and be connected to the conductive patterns and the isolation conductive patterns. In an example, the plurality of word line contacts WCT may be respectively connected to the first conductive patterns 511 of the first stack structure 510, the third conductive patterns 531 of the third stack structure 530, and the first isolation conductive patterns 581 of the first isolation stack structure 580.

In the semiconductor device in accordance with this embodiment, the first and second isolation stack structures 580 and 590 are provided, so that the space between the fifth and sixth stack structures 550 and 560 can be formed to be partially narrow. Accordingly, when the space between the first and second stack structures 510 and 520, the space between the third and fourth stack structures 530 and 540, and the space between the fifth and sixth stack structures 550 and 560 are filled with the second insulating layer, any void can be suppressed from being formed in the second insulating layer, and the structural stability of the semiconductor device can be improved.

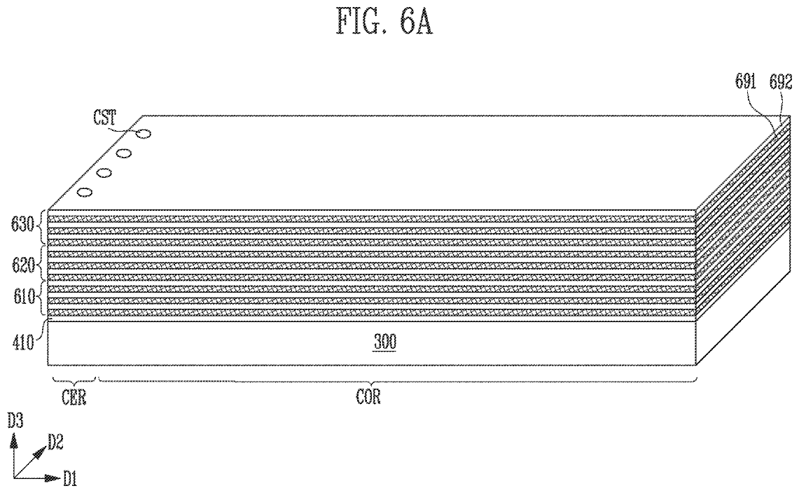

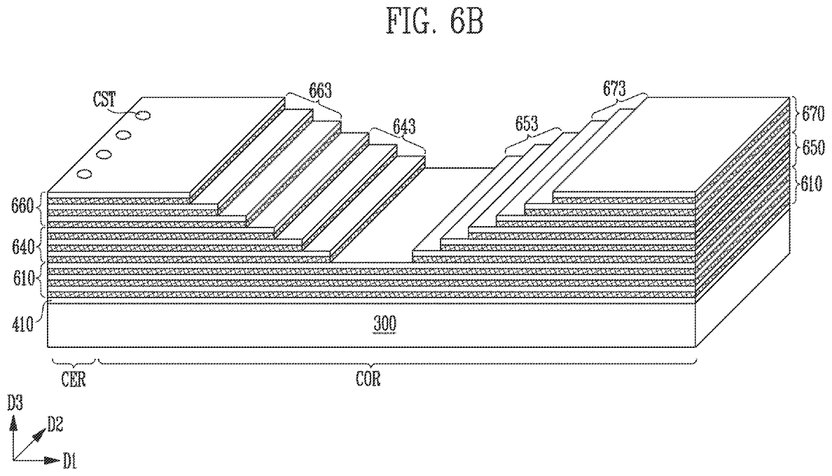

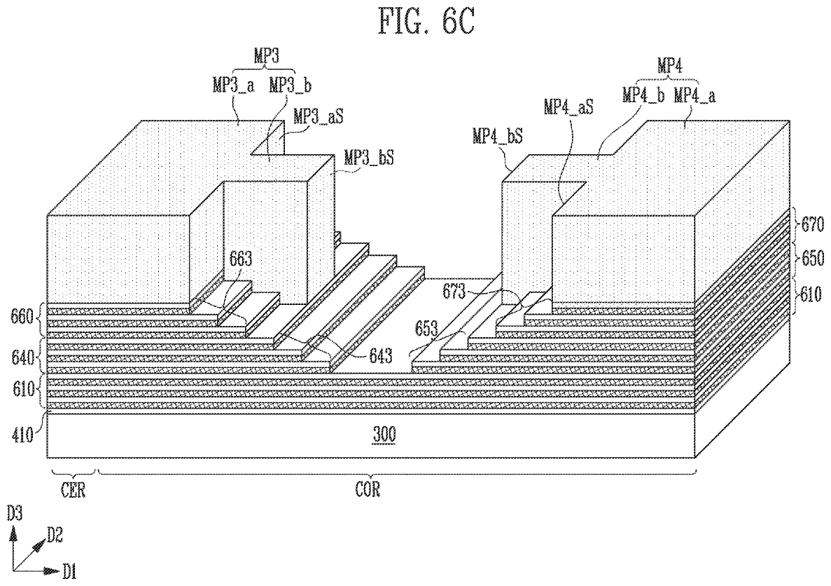

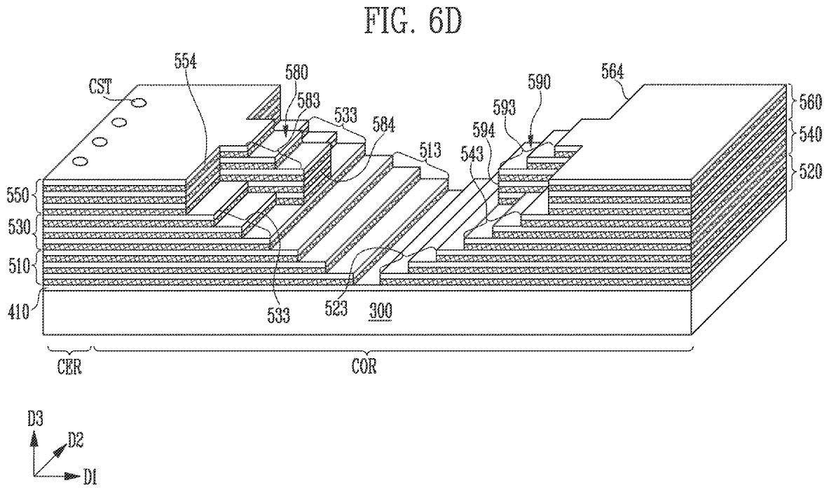

FIGS. 6A, 6B, 6C, and 6D are perspective views illustrating a manufacturing method of the semiconductor device shown in FIGS. 5A and 5B. For convenience of description, components identical to those described with reference to FIGS. 5A and 5B are designated by like reference numerals, and their overlapping descriptions will be omitted. A manufacturing method described below is merely one embodiment of the manufacturing method of the semiconductor memory device shown in FIGS. 5A and 5B, and the manufacturing method of the semiconductor memory device shown in FIGS. 5A and 5B might not be limited to that described below.

Referring to FIG. 6A, a first insulating layer 410 may be formed on a base part 300.

First to third preliminary stack structures 610, 620, and 630 may be sequentially formed on the first insulating layer 410. Each of the first to third preliminary stack structures 610, 620, and 630 may include preliminary insulating layers 692 and preliminary sacrificial layers 691, alternately stacked in a third direction D3.

Cell plugs CST that penetrate the first to third preliminary stack structures 610, 620, and 630 and the first insulating layer 410 may be formed in a cell region CER.

Referring to FIG. 6B, the second and third preliminary stack structures 620 and 630 may be etched in a stepped shape in a connection region COR. When the second and third preliminary stack structures 620 and 630 are etched, fourth to seventh preliminary stack structures 640, 650, 660, and 670 may be formed on the first preliminary stack structure 610. When the second preliminary stack structure 620 is etched, the fourth and fifth preliminary stack structure 640 and 650 may be formed. When the third preliminary stack structure 630 is etched, the sixth and seventh preliminary stack structures 660 and 670 may be formed. The sixth and seventh preliminary stack structures 660 and 670 may be disposed at a higher level than the level of the fourth and fifth preliminary stack structures 640 and 650.

The fourth preliminary stack structure 640 may include a seventh stepped structure 643. The fifth preliminary stack structure 650 may include an eighth stepped structure 653. The sixth preliminary stack structure 660 may include a ninth stepped structure 663. The seventh preliminary stack structure 670 may include a tenth stepped structure 673. The seventh and eighth stepped structures 643 and 653 may have a structure in which the seventh and eighth stepped structures 643 and 653 are symmetrical. The ninth and tenth stepped structures 663 and 673 may have a structure in which the ninth and tenth stepped structures 663 and 673 are symmetrical.

Referring to FIG. 6C, a third mask pattern MP3 may be formed on the sixth preliminary stack structure 660, and a fourth mask pattern MP4 may be formed on the seventh preliminary stack structure 670.

The third mask pattern MP3 may include a first part MP3_a and a second part MP3_b. The first part MP3_a may cover an uppermost surface of the sixth preliminary stack structure 660. The second part MP3_b may protrude in a first direction D1 from a sidewall MP3_aS of the first part MP3_a. The second part MP3_b may cover a portion of a surface of the ninth stepped structure 663 of the sixth preliminary stack structure 660. Another portion of the surface of the ninth stepped structure 663 of the sixth preliminary stack structure 660 may be exposed by the second part MP3_b. The surface of the ninth stepped structure 663 of the sixth preliminary stack structure 660 may include a portion covered by the second part MP3_b and a portion which is not covered by the second part MP3_b. A sidewall MP3_bS of the second part MP3_b may be parallel to the sidewall MP3_aS of the first part MP3_a. The sidewall MP3_bS of the second part MP3_b may be a sidewall of the second part MP3_b, which is adjacent to the seventh stepped structure 643 of the fourth preliminary stack structure 640.

The fourth mask pattern MP4 may include a first part MP4_a and a second part MP4_b. The first part MP4_a may cover an uppermost surface of the seventh preliminary stack structure 670. The second part MP4_b may protrude in the first direction D1 from a sidewall MP4_aS of the first part MP4_a. The second part MP4_b may cover a portion of a surface of the tenth stepped structure 673 of the seventh preliminary stack structure 670. Another portion of the surface of the tenth stepped structure 673 of the seventh preliminary stack structure 670 may be exposed by the second part MP4_b. The surface of the tenth stepped structure 673 of the seventh preliminary stack structure 670 may include a portion covered by the second part MP4_b and a portion which is not covered by the second part MP4_b. A sidewall MP4_bS of the second part MP4_b may be parallel to the sidewall MP4_aS of the first part MP4_a. The sidewall MP4_bS of the second part MP4_b may be a sidewall of the second part MP4_b, which is adjacent to the eighth stepped structure 653 of the fifth preliminary stack structure 650.

Referring to FIG. 6D, the first, fourth, fifth, sixth, and seventh preliminary stack structures 610, 640, 650, 660, and 670 may be etched by using, as an etching barrier, the third mask pattern MP3 and the fourth mask pattern MP4.

First and second stack structures 510 and 520 may be formed by etching the first preliminary stack structure 610. A first stepped structure 513 of the first stack structure 510 may be formed by etching the seventh stepped structure 643 of the fourth preliminary stack structure 640 uniformly. The first stepped structure 513 of the first stack structure 510 may be formed by transferring the seventh stepped structure 643 of the fourth preliminary stack structure 640 downwardly. A second stepped structure 523 of the second stack structure 520 may be formed by etching the eighth stepped structure 653 of the fifth preliminary stack structure 650 uniformly. The second stepped structure 523 of the second stack structure 520 may be formed by transferring the eighth stepped structure 653 of the fifth preliminary stack structure 650 downwardly.

A third stack structure 530 may be formed by etching the fourth preliminary stack structure 640. A third stepped structure 533 of the third stack structure 530 may be formed by etching the ninth stepped structure 663 of the sixth preliminary stack structure 660 uniformly. The third stepped structure 533 of the third stack structure 530 may be formed by transferring the ninth stepped structure 663 of the sixth preliminary stack structure 660 downwardly. A portion of the ninth stepped structure 663, which is not covered by the second part MP3_b of the third mask pattern MP3, may be etched uniformly, to form the third stepped structure 533. The portion of the ninth stepped structure 663, which is not covered by the second part MP3_b of the third mask pattern MP3, may be transferred downwardly, to form the third stepped structure 533.

A fourth stack structure 540 may be formed by etching the fifth preliminary stack structure 650. A fourth stepped structure 543 of the fourth stack structure 540 may be formed by etching the tenth stepped structure 673 of the seventh preliminary stack structure 670 uniformly. The fourth stepped structure 543 of the fourth stack structure 540 may be formed by transferring the tenth stepped structure 673 of the seventh preliminary stack structure 670 downwardly. A portion of the tenth stepped structure 673, which is not covered by the second part MP4_b of the fourth mask pattern MP4, may be etched uniformly, to form the fourth stepped structure 543. The portion of the tenth stepped structure 673, which is not covered by the second part MP4_b of the fourth mask pattern MP4, may be transferred downwardly, to form the fourth stepped structure 543.

A fifth stack structure 550 and a first isolation stack structure 580 may be formed by etching the sixth preliminary stack structure 660. The fifth stack structure 550 and the first isolation stack structure 580 may be portions of the sixth preliminary stack structure 660, which remain in the etching process by the third mask pattern MP3.

A portion of the sixth preliminary stack structure 660, which overlaps with the first part MP3_a of the third mask pattern MP3, may remain, to form the fifth stack structure 550. A sidewall 554 of the fifth stack structure 550 may be formed that corresponds to the sidewall MP3_aS of the first part MP3_a of the third mask pattern MP3.

A portion of the sixth preliminary stack structure 660, which overlaps with the second part MP3_b of the third mask pattern MP3, may remain, to form the first isolation stack structure 580. The fifth stepped structure 583 of the first isolation stack structure 580 may be a portion of the ninth stepped structure 663 of the sixth preliminary stack structure 660, which remains in the etching process by the second part MP3_b of the third mask pattern MP3. A third sidewall 584 of the first isolation stack structure 580 may be formed that corresponds to the sidewall MP3_bS of the second part MP3_b of the third mask pattern MP3.

A sixth stack structure 560 and a second isolation stack structure 590 may be formed by etching the seventh preliminary stack structure 670. The sixth stack structure 560 and the second isolation stack structure 590 may be portions of the seventh preliminary stack structure 670, which remain in the etching process by the fourth mask pattern MP4.

A portion of the seventh preliminary stack structure 670, which overlaps with the first part MP4_a of the fourth mask pattern MP4, may remain, to form the sixth stack structure 560. A second sidewall 564 of the sixth stack structure 560 may be formed that corresponds to the sidewall MP4_aS of the first part MP4_a of the fourth mask pattern MP4.

A portion of the seventh preliminary stack structure 670, which overlaps with the second part MP4_b of the fourth mask pattern MP4, may remain, to form the second isolation stack structure 590. A sixth stepped structure of the second isolation stack structure 590 may be a portion of the tenth stepped structure 673 of the seventh preliminary stack structure 670, which remains in the etching process by the second part MP4_b of the fourth mask pattern MP4. A fourth sidewall 594 of the second isolation stack structure 590 may be formed that corresponds to the sidewall MP4_bS of the second part MP4_b of the fourth mask pattern MP4.

Subsequently, a second insulating layer may be formed, which covers the first to sixth stack structures 510, 520, 530, 540, 550, and 560 and the first and second isolation stack structures 580 and 590.

Subsequently, sacrificial patterns of the first to sixth stack structures 510, 520, 530, 540, 550, and 560 and the first and second isolation stack structures 580 and 590 may be replaced with conductive patterns.

Subsequently, word line contacts may be formed, which are connected to the conductive patterns.

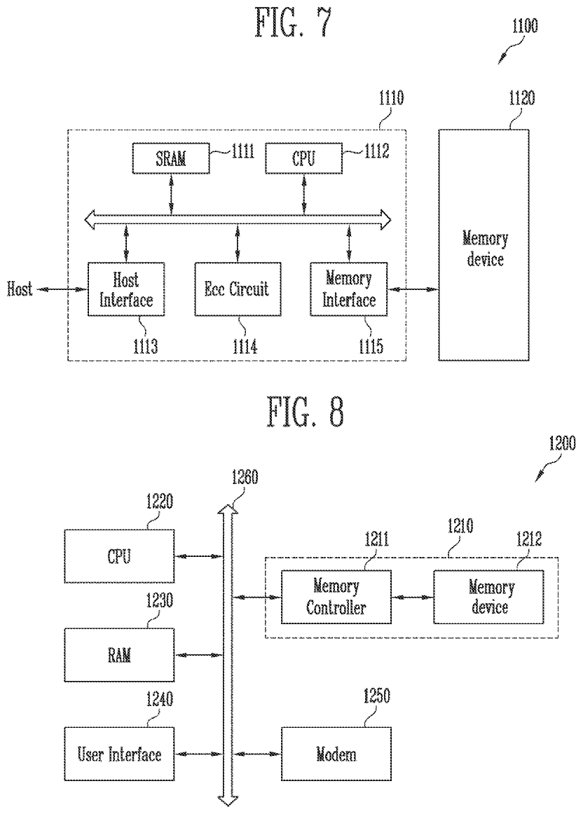

FIG. 7 is a block diagram, illustrating a configuration of a memory system in accordance with an embodiment of the present disclosure.

Referring to FIG. 7, the memory system 1100 in accordance with the embodiment of the present disclosure includes a memory device 1120 and a memory controller 1110.

The memory device 1120 may include the semiconductor device described above. The memory device 1120 may be a multi-chip package configured with a plurality of flash memory chips.

The memory controller 1110 is configured to control the memory device 1120, and may include a Static Random Access Memory (SRAM) 1111, a Central Processing Unit (CPU) 1112, a host interface 1113, an Error Correction Code (ECC) circuit 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The ECC circuit 1114 detects and corrects an error included in a data read from the memory device 1120, and the memory interface 1115 interfaces with the memory device 1120. In addition, the memory controller 1110 may further include an ROM for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer Small Interface (SCSI) protocol, an Enhanced Small Disk Interface (ESDI) protocol, and an Integrated Drive Electronics (IDE) protocol.

FIG. 8 is a block diagram, illustrating a configuration of a computing system in accordance with an embodiment of the present disclosure.

Referring to FIG. 8, the computing system 1200 in accordance with the embodiment of the present disclosure may include a CPU 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, a Camera Image Processor (CIS), a mobile D-RAM, and the like may be further included.

The memory system 1210 may be configured with a memory device 1212 and a memory controller 1211 as described with reference to FIG. 7.

In the semiconductor device, in accordance with the present disclosure, a protrusion stack structure is formed on a stack structure with a stepped structure, so that any void can be suppressed from being formed in an insulating layer covering the stepped structure. Accordingly, any crack can be prevented from being formed in the insulating layer, and the structural stability of the semiconductor structure can be improved.

The exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

So far as not being differently defined, all terms used herein with technical or scientific terminologies have meanings that they are commonly understood by those skilled in the art to which the present disclosure pertains. The terms with the definitions as defined in the dictionary should be understood such that they have meanings consistent with the context of the related technique. So far as not being clearly defined in this application, terms should not be understood in an ideally or excessively formal way.

What is claimed is:

1. A semiconductor device comprising:
a first stack structure with first insulating patterns and first conductive patterns, alternately stacked, the first stack structure with a first stepped structure that is defined by the first insulating patterns and the first conductive patterns;
a second stack structure with second insulating patterns and second conductive patterns, alternately stacked on the first stack structure; and
a first protrusion stack structure protruding toward the first stepped structure from the second stack structure, the first protrusion stack structure with first protrusion insulating patterns and first protrusion conductive patterns, alternately stacked on the first stack structure,
wherein a sidewall of the first protrusion stack structure includes side surfaces of the first protrusion insulating patterns and side surfaces of the first protrusion conductive patterns, which form a common surface.

2. The semiconductor device of claim 1, wherein the first protrusion stack structure is spaced apart from the first stepped structure.

3. The semiconductor device of claim 2, wherein the shortest distance between the first protrusion stack structure and the first stepped structure is smaller than a distance between the second stack structure and the first stepped structure.

4. The semiconductor device of claim 1, wherein the second stack structure includes a second stepped structure that is defined by the second insulating patterns and the second conductive patterns.

5. The semiconductor device of claim 1, wherein a width of the first protrusion stack structure is smaller than a width of the second stack structure, and
wherein the width of the first protrusion stack structure and the width of the second stack structure are measurements in a lateral direction.

6. The semiconductor device of claim 1, further comprising a third stack structure with third insulating patterns, third conductive patterns, and a third stepped structure that is defined by the third insulating patterns and the third conductive patterns,
wherein the third stack structure is disposed at the same level as the first stack structure, and
wherein the third stepped structure and the first stepped structure are symmetrical.

7. The semiconductor device of claim 6, further comprising:
a fourth stack structure disposed on the third stack structure, the fourth stack structure with fourth insulating patterns and fourth conductive patterns; and
a second protrusion stack structure protruding laterally toward the third stepped structure from the fourth stack structure, the second protrusion stack structure with second protrusion insulating patterns and second protrusion conductive patterns, alternately stacked on the third stack structure,
wherein the second protrusion stack structure protrudes laterally in an opposite direction compared to the first protrusion stack structure, and
wherein a sidewall of the second protrusion stack structure includes side surfaces of the second protrusion insulating patterns and side surfaces of the second protrusion conductive patterns, which form a common surface.

8. The semiconductor device of claim 7, wherein the shortest distance between the first and second protrusion stack structures is smaller than a distance between the second and fourth stack structures.

9. The semiconductor device of claim 1, wherein the first protrusion stack structure and the second stack structure are continuously formed without any boundary.

10. The semiconductor device of claim 1, wherein the first protrusion insulating patterns and the second insulating patterns are continuously formed without any boundary, and
the first protrusion conductive patterns and the second conductive patterns are continuously formed without any boundary.

11. The semiconductor device of claim 1, wherein the first stepped structure includes step top surfaces and step side surfaces, and
wherein the step side surfaces are parallel to the sidewall of the first protrusion stack structure.

12. A semiconductor device comprising:
a first stack structure with first insulating patterns and first conductive patterns, alternately stacked, the first stack structure with a first stepped structure that is defined by the first insulating patterns and the first conductive patterns;
a second stack structure with second insulating patterns and second conductive patterns, alternately stacked, the second stack structure with a second stepped structure that is defined by the second insulating patterns and the second conductive patterns;
a third stack structure with third insulating patterns and third conductive patterns, alternately stacked on the first stack structure;
a fourth stack structure with fourth insulating patterns and fourth conductive patterns, alternately stacked on the second stack structure; and
an insulating part that is filled between the first and second stack structures and between the third and fourth stack structures,
wherein an upper portion of the insulating part includes first parts and a second part, the second part with a width that is smaller than a width of the first parts.

13. The semiconductor device of claim 12, wherein the second part is disposed between the first parts.

14. The semiconductor device of claim 12, further comprising a first protrusion stack structure with first protrusion insulating patterns and first protrusion conductive patterns, alternately stacked on the first stack structure,
wherein the first protrusion stack structure is disposed between the first parts.

15. The semiconductor device of claim 14, wherein a sidewall of the first protrusion stack structure includes side surfaces of the first protrusion insulating patterns and side surfaces of the first protrusion conductive patterns, forming a common surface.

16. The semiconductor device of claim 14, wherein a sidewall of the first protrusion stack structure is flat.

17. The semiconductor device of claim 14, wherein a distance between the first protrusion stack structure and the first stepped structure is smaller than a distance between the third stack structure and the first stepped structure.

18. The semiconductor device of claim 12, wherein a lower portion of the insulating part is disposed between the first and second stepped structures.

19. A semiconductor device comprising:
a first stack structure with first insulating patterns and first conductive patterns, alternately stacked, the first stack structure with first stepped structure that is defined by the first insulating patterns and the first conductive patterns; and
a first isolation stack structure disposed on the first stepped structure, the first isolation stack structure with first isolation insulating patterns and first isolation conductive patterns, alternately stacked,
wherein the first isolation stack structure includes a second stepped structure defined by the first isolation insulating patterns and the first isolation conductive patterns, and
wherein the second stepped structure is disposed at a higher level than a level of the first stepped structure.

20. The semiconductor device of claim 19, further comprising a second stack structure with second insulating patterns and second conductive patterns, alternately stacked on the first stack structure,
wherein the second stack structure includes a first sidewall that is defined by sidewalls of the second insulating patterns and sidewalls of the second conductive patterns, forming a common surface, and
wherein the first stepped structure and the first isolation stack structure are connected to the first sidewall.
